(19) United States
(12) Patent Application Publication
(10) Pub. No.: US 2025/0212541 A1
(43) Pub. Date: Jun. 26, 2025

(54) SOLID-STATE IMAGING DEVICE

(71) Applicant: SONY SEMICONDUCTOR SOLUTIONS CORPORATION, Kanagawa (JP)

(72) Inventors: Nobuyuki OHBA, Kumamoto (JP); Yukihiro SAYAMA, Kumamoto (JP); Sintaro NAKAJIKI, Kumamoto (JP); Yoshikazu TANAKA, Kumamoto (JP)

(73) Assignee: SONY SEMICONDUCTOR SOLUTIONS CORPORATION, Kanagawa (JP)

(21) Appl. No.: 18/851,951

(22) PCT Filed: Mar. 13, 2023
(86) PCT No.: PCT/JP2023/009661

§ 371 Date: Sep. 27, 2024

(30) Foreign Application Priority Data
Apr. 20, 2022 (JP) 2022-069621

(51) Int. Cl. H10F 39/00; H10F 39/18

(52) U.S. Cl. CPC H10F 39/8053; H10F 39/024; H10F 39/182; H10F 39/8063

(57) ABSTRACT

A solid-state imaging device includes: a color filter disposed at a position corresponding to each of pixels; an optical lens stacked on the color filter, an inter-lens partition wall disposed on at least a portion of a periphery of a side surface of the optical lens at a corresponding position between the pixels; and a protective film that is stacked on the color filter between the color filter and the inter-lens partition wall, and protects the color filter.

### TECHNICAL FIELD

The present disclosure relates to a solid-state imaging device.

### BACKGROUND ART

PTL 1 listed below discloses a solid-state imaging device. In the solid-state imaging device, a plurality of pixels is arrayed in matrix. The pixel includes a photoelectric conversion element (photodiode) that converts light into electric charge. In the pixel, a color filter is disposed on the photoelectric conversion element, and an on-chip lens is further disposed on the color filter.

A partition wall (first wall) is formed between color filters corresponding to adjacent pixels. Likewise, a partition wall (second wall) is formed also between on-chip lenses corresponding to adjacent pixels.

Providing such a partition wall makes it possible to improve color mixture of adjacent pixels in the solid-state imaging device.

### CITATION LIST

### Patent Literature

PTL 1: Japanese Unexamined Patent Application Publication No. 2021-158374

### SUMMARY OF THE INVENTION

In a solid-state imaging device described above, a partition wall is formed between on-chip lenses after formation of a color filter. The formation of the partition wall involves use of dry etching, for example. It is therefore desired, in a solid-state imaging device, to construct a partition wall between on-chip lenses without damaging a color filter.

A solid-state imaging device according to an embodiment of the present disclosure includes: a color filter disposed at a position corresponding to each of pixels; an optical lens stacked on the color filter; an inter-lens partition wall disposed on at least a portion of a periphery of a side surface of the optical lens at a corresponding position between the pixels; and a protective film that is stacked on the color filter between the color filter and the inter-lens partition wall, and protects the color filter.

Further, a solid-state imaging device according to an embodiment is provided, on a first surface of the protective film on a side of the optical lens, with an irregularity that is larger than a second surface thereof on a side of the color filter.

### BRIEF DESCRIPTION OF THE DRAWINGS

FIG. 1 is a main part cross-sectional view of a pixel region of a solid-state imaging device according to a first embodiment of the present disclosure.

FIG. 2 is a plan view of an overall configuration (chip layout) of the solid-state imaging device according to the first embodiment.

FIG. 3 is an explanatory first step cross-sectional view corresponding to FIG. 1 of a manufacturing method of the solid-state imaging device according to the first embodiment.

FIG. 4 is a second step cross-sectional view.

FIG. 5 is a third step cross-sectional view.

FIG. 6 is a fourth step cross-sectional view.

FIG. 7 is a fifth step cross-sectional view.

FIG. 8 is a sixth step cross-sectional view.

FIG. 9 is a seventh step cross-sectional view.

FIG. 10 is a main part plan view of a pixel region of a solid-state imaging device according to a second embodiment of the present disclosure.

FIG. 11 is a main part cross-sectional view corresponding to FIG. 1 of the pixel region illustrated in FIG. 10 (a cross-sectional view taken along a section line A-A illustrated in FIG. 10).

FIG. 12 is a main part cross-sectional view corresponding to FIG. 1 of the pixel region illustrated in FIG. 10 (a cross-sectional view taken along a section line B-B illustrated in FIG. 10).

FIG. 13 is a main part cross-sectional view corresponding to FIG. 12 of a pixel region of a solid-state imaging device according to a modification example of the second embodiment.

FIG. 14 is a main part plan view corresponding to FIG. 10 of a pixel region of a solid-state imaging device according to a third embodiment of the present disclosure.

FIG. 15 is a main part cross-sectional view corresponding to FIG. 11 of the pixel region illustrated in FIG. 14 (a cross-sectional view taken along a section line C-C illustrated in FIG. 14).

FIG. 16 is a main part cross-sectional view corresponding to FIG. 12 of the pixel region illustrated in FIG. 14 (a cross-sectional view taken along a section line D-D illustrated in FIG. 14).

FIG. 17 is a main part cross-sectional view corresponding to FIG. 1 of a pixel region of a solid-state imaging device according to a fourth embodiment of the present disclosure.

FIG. 18 is a main part cross-sectional view corresponding to FIG. 1 of a pixel region of a solid-state imaging device according to a fifth embodiment of the present disclosure.

FIG. 19 is a main part cross-sectional view corresponding to FIG. 1 of a pixel region of a solid-state imaging device according to a sixth embodiment of the present disclosure.

FIG. 20 is a main part cross-sectional view corresponding to FIG. 1 of a pixel region of a solid-state imaging device according to a seventh embodiment of the present disclosure.

FIG. 21 is a main part cross-sectional view corresponding to FIG. 1 of a pixel region of a solid-state imaging device according to an eighth embodiment of the present disclosure.

FIG. 22 is a main part cross-sectional view corresponding to FIG. 1 of a pixel region of a solid-state imaging device according to a ninth embodiment of the present disclosure.

FIG. 23 is a main part cross-sectional view corresponding to FIG. 1 of a pixel region of a solid-state imaging device according to a tenth embodiment of the present disclosure.

FIG. 24 is a main part cross-sectional view corresponding to FIG. 1 of a pixel region of a solid-state imaging device according to an eleventh embodiment of the present disclosure.

FIG. 25 is a main part cross-sectional view corresponding to FIG. 1 of a middle portion of a pixel region in a solid-state imaging device according to a twelfth embodiment of the present disclosure.

FIG. 26 is a main part cross-sectional view corresponding to FIG. 1 of a peripheral portion of a pixel region in the solid-state imaging device according to the twelfth embodiment.

FIG. 27 is a main part cross-sectional view corresponding to FIG. 1 of a pixel region in a solid-state imaging device according to a thirteenth embodiment of the present disclosure.

FIG. 28 is a main part cross-sectional view corresponding to FIG. 1 of a pixel region in a solid-state imaging device according to a fourteenth embodiment of the present disclosure.

FIG. 29 is a main part cross-sectional view corresponding to FIG. 1 of a pixel region in a solid-state imaging device according to a fifteenth embodiment of the present disclosure.

FIG. 30 is a main part cross-sectional view corresponding to FIG. 1 of a pixel region in a solid-state imaging device according to a sixteenth embodiment of the present disclosure.

FIG. 31 is a main part cross-sectional view corresponding to FIG. 1 of a pixel region in a solid-state imaging device according to a modification example of the sixteenth embodiment.

FIG. 32 is a main part cross-sectional view corresponding to FIG. 1 of a pixel region in a solid-state imaging device according to a seventeenth embodiment of the present disclosure.

FIG. 33 is a main part cross-sectional view corresponding to FIG. 1 of a pixel region in a solid-state imaging device according to an eighteenth embodiment of the present disclosure.

FIG. 34 is a main part cross-sectional view corresponding to FIG. 1 of a pixel region in a solid-state imaging device according to a nineteenth embodiment of the present disclosure.

FIG. 35 is a main part plan view corresponding to FIG. 10 of a pixel region of a solid-state imaging device according to a twentieth embodiment of the present disclosure.

FIG. 36 is a main part cross-sectional view corresponding to FIG. 11 of the pixel region illustrated in FIG. 35 (a cross-sectional view taken along a section line E-E illustrated in FIG. 35).

FIG. 37 is a main part cross-sectional view corresponding to FIG. 12 of the pixel region illustrated in FIG. 35 (a cross-sectional view taken along a section line F-F illustrated in FIG. 35).

FIG. 38 is an explanatory first step cross-sectional view corresponding to FIG. 35 of a manufacturing method of the solid-state imaging device according to the twentieth embodiment.

FIG. 39 is a second step cross-sectional view.

FIG. 40 is a third step cross-sectional view.

FIG. 41 is a fourth step cross-sectional view.

FIG. 42 is a fifth step cross-sectional view.

FIG. 43 is a sixth step cross-sectional view.

FIG. 44 is a seventh step cross-sectional view.

FIG. 45 is an eighth step cross-sectional view.

FIG. 46 is a ninth step cross-sectional view.

FIG. 47 is a main part cross-sectional view corresponding to FIG. 1 of a pixel region in a solid-state imaging device according to a twenty-first embodiment of the present disclosure.

FIG. 48 is a main part cross-sectional view corresponding to FIG. 1 of a pixel region in a solid-state imaging device according to a twenty-second embodiment of the present disclosure.

FIG. 49 is a main part cross-sectional view corresponding to FIG. 1 of a pixel region in a solid-state imaging device according to a twenty-third embodiment of the present disclosure (a cross-sectional view taken along a section line G-G illustrated in FIG. 50).

FIG. 50 is a main part plan view of the pixel region of the solid-state imaging device according to the twenty-third embodiment.

FIG. 51 is an explanatory main part cross-sectional view corresponding to FIG. 49 of a phase difference detection image of a phase difference detection pixel taken along the section line G-G illustrated in FIG. 50.

FIG. 52 is an explanatory main part cross-sectional view corresponding to FIG. 49 of a phase difference detection image of a phase difference detection pixel taken along a section line H-H illustrated in FIG. 50.

FIG. 53 is an explanatory graph of a relationship between an incident angle and an output upon detection of a phase difference of the phase difference detection pixel illustrated in FIGS. 51 and 52.

FIG. 54 is a main part plan view corresponding to FIG. 50 of a pixel region of a solid-state imaging device according to a twenty-fourth embodiment of the present disclosure.

FIG. 55 is a main part plan view schematically illustrating the entirety of a pixel region in a solid-state imaging device according to a twenty-fifth embodiment of the present disclosure.

FIG. 56 is a main part cross-sectional view corresponding to FIG. 49 of a pixel disposed in a region A1 of a middle portion of the pixel region illustrated in FIG. 55.

FIG. 57 is a main part cross-sectional view corresponding to FIG. 49 of a pixel disposed in a region A2 between the middle portion and a peripheral portion of the pixel region illustrated in FIG. 55.

FIG. 58 is a main part cross-sectional view corresponding to FIG. 49 of a pixel disposed in a region A3 of the peripheral portion of the pixel region illustrated in FIG. 55.

FIG. 59 is a main part plan view corresponding to FIG. 50 of a pixel region of a solid-state imaging device according to a twenty-sixth embodiment of the present disclosure.

FIG. 60 is a main part plan view corresponding to FIG. 50 of a pixel region of a solid-state imaging device according to a twenty-seventh embodiment of the present disclosure.

FIG. 61 is a block diagram depicting an example of schematic configuration of a vehicle control system.

FIG. 62 is a diagram of assistance in explaining an example of installation positions of an outside-vehicle information detecting section and an imaging section.

### MODES FOR CARRYING OUT THE INVENTION

Hereinafter, description is given in detail of embodiments of the present disclosure with reference to the drawings. It is to be noted that the description is given in the following order.

### 1. First Embodiment

A first embodiment describes an example in which the present technology is applied to a solid-state imaging device. Here, description is given of a schematic configuration of the entirety of the solid-state imaging device, a basic configuration of a pixel in a pixel region, and a manufacturing method of the solid-state imaging device.

### 2. Second Embodiment

A second embodiment describes a first example in which a structure of an inter-lens partition wall disposed between optical lenses is replaced in the solid-state imaging device according to the first embodiment.

### 3. Third Embodiment

A third embodiment describes a second example in which the structure of the inter-lens partition wall is replaced in the solid-state imaging device according to the first embodiment.

### 4. Fourth Embodiment

A fourth embodiment describes a third example in which the structure of the inter-lens partition wall is replaced in the solid-state imaging device according to the first embodiment.

### 5. Fifth Embodiment

A fifth embodiment describes a first example in which a structure of a protective film disposed in a color filter is replaced in the solid-state imaging device according to the first embodiment.

### 6. Sixth Embodiment

A sixth embodiment describes a fourth example in which the structure of the inter-lens partition wall is replaced in the solid-state imaging device according to the first embodiment.

### 7. Seventh Embodiment

A seventh embodiment describes a fifth example in which the structure of the inter-lens partition wall is replaced in the solid-state imaging device according to the first embodiment.

### 8. Eighth Embodiment

An eighth embodiment describes a second example in which the structure of the protective film disposed on the color filter is replaced in the solid-state imaging device according to the first embodiment.

### 9. Ninth Embodiment

A ninth embodiment describes a third example in which the structure of the protective film disposed on the color filter is replaced in the solid-state imaging device according to the first embodiment.

### 10. Tenth Embodiment

A tenth embodiment describes a fourth example in which the structure of the protective film disposed on the color filter is replaced in the solid-state imaging device according to the first embodiment.

### 11. Eleventh Embodiment

An eleventh embodiment describes a fifth example in which the structure of the protective film disposed on the color filter is replaced in the solid-state imaging device according to the first embodiment.

### 12. Twelfth Embodiment

A twelfth embodiment describes a sixth example in which the structure of the protective film disposed on the color filter is replaced in the solid-state imaging device according to the first embodiment.

### 13. Thirteenth Embodiment

A thirteenth embodiment describes a seventh example in which the structure of the protective film disposed on the color filter is replaced in the solid-state imaging device according to the first embodiment.

### 14. Fourteenth Embodiment

A fourteenth embodiment describes a first example in which a structure of an inter-filter partition wall disposed between color filters is replaced in the solid-state imaging device according to the first embodiment.

### 15. Fifteenth Embodiment

A fifteenth embodiment describes a second example in which the structure of the inter-filter partition wall is replaced in the solid-state imaging device according to the first embodiment.

### 16. Sixteenth Embodiment

A sixteenth embodiment describes a first example in which a structure of an optical lens is replaced in the solid-state imaging device according to the first embodiment.

### 17. Seventeenth Embodiment

A seventeenth embodiment describes an example in which a structure of a color filter is replaced in the solid-state imaging device according to the first embodiment.

### 18. Eighteenth Embodiment

An eighteenth embodiment describes a second example in which the structure of the optical lens is replaced in the solid-state imaging device according to the first embodiment.

### 19. Nineteenth Embodiment

A nineteenth embodiment describes a third example in which the structure of the optical lens is replaced in the solid-state imaging device according to the first embodiment.

### 20. Twentieth Embodiment

A twentieth embodiment describes a fourth example in which the structure of the optical lens is replaced in the solid-state imaging device according to the first embodiment. Here, description is also given of a basic configuration of a pixel and a manufacturing method of the solid-state imaging device.

### 21. Twenty-First Embodiment

A twenty-first embodiment describes a first example in which the structure of the inter-lens partition wall is replaced in the solid-state imaging device according to the twentieth embodiment.

### 22. Twenty-Second Embodiment

A twenty-second embodiment describes a second example in which the structure of the inter-lens partition wall is replaced in the solid-state imaging device according to the twentieth embodiment.

### 23. Twenty-Third Embodiment

A twenty-third embodiment describes a first example in which a phase difference detection pixel is further provided and a structure of an inter-lens partition wall of the phase difference detection pixel is replaced in the solid-state imaging device according to the first embodiment.

### 24. Twenty-Fourth Embodiment

A twenty-fourth embodiment describes a second example in which the structure of the inter-lens partition wall of the phase difference detection pixel is replaced in the solid-state imaging device according to the twenty-third embodiment.

### 25. Twenty-Fifth Embodiment

A twenty-fifth embodiment describes a third example in which the structure of the inter-lens partition wall of the phase difference detection pixel is replaced in the solid-state imaging device according to the twenty-third embodiment.

### 26. Twenty-Sixth Embodiment

A twenty-sixth embodiment describes a fourth example in which the structure of the inter-lens partition wall of the phase difference detection pixel is replaced in the solid-state imaging device according to the twenty-third embodiment.

### 27. Twenty-Seventh Embodiment

A twenty-seventh embodiment describes a fifth example in which the structure of the inter-lens partition wall of the phase difference detection pixel is replaced in the solid-state imaging device according to the twenty-third embodiment.

### 28. Example of Practical Application to Mobile Body

This practical application example describes an example in which the present technology is applied to a mobile body.

### 29. Other Embodiments

### 1. First Embodiment

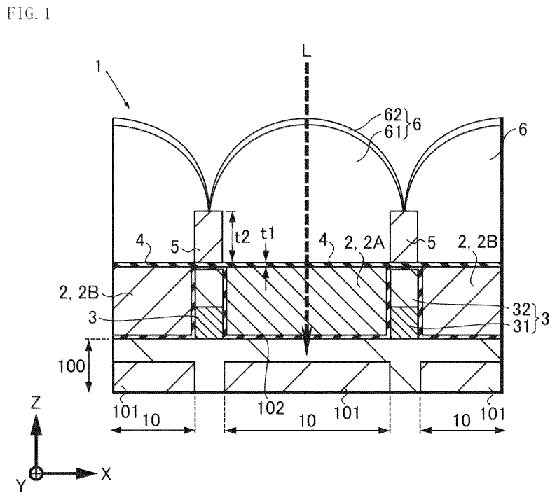

Description is given of a solid-state imaging device 1 according to the first embodiment of the present disclosure with reference to FIGS. 1 to 9.

Here, an arrow-X direction indicated as appropriate in the drawings indicates one planar direction of the solid-state imaging device 1 placed on a plane for convenience. An arrow-Y direction indicates another planar direction orthogonal to the arrow-X direction. In addition, an arrow-Z direction indicates an upward direction orthogonal to the arrow-X direction and the arrow-Y direction. That is, the arrow-X direction, the arrow-Y direction, and the arrow-Z direction exactly coincide with an X-axis direction, a Y-axis direction, and a Z-axis direction, respectively, of a three-dimensional coordinate system.

It is to be noted that these directions are each indicated to aid understanding of descriptions, and are not intended to limit directions used in the present technology.

### [Configuration of Solid-State Imaging Device 1]

### (1) Overall Configuration of Solid-State Imaging Device 1

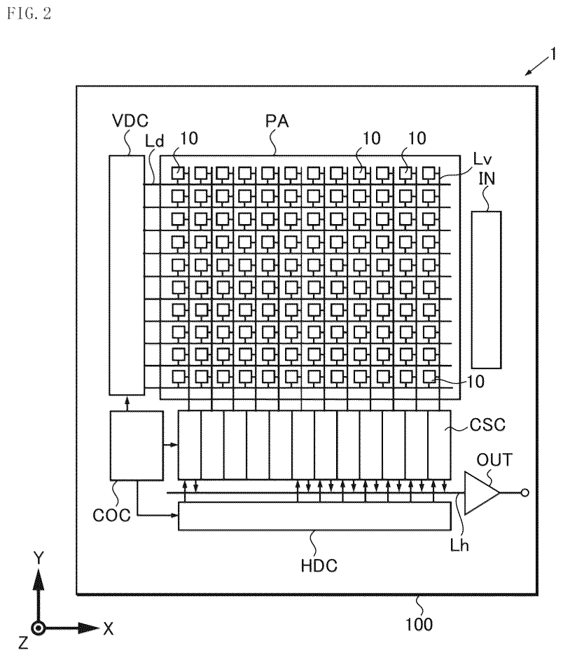

FIG. 2 illustrates an example of a planar configuration of the entirety of the solid-state imaging device 1. The solid-state imaging device 1 according to the first embodiment is constructed using a substrate 100. For example, a semiconductor substrate is used for the substrate 100. Specifically, a single-crystalline silicon (Si) substrate is used as the semiconductor substrate. The substrate 100 is formed in a rectangular shape as viewed in the arrow-Z direction (hereinafter, simply referred to as “in a plan view”).

The solid-state imaging device 1 includes at least a pixel region PA, a vertical drive circuit VDC, a column signal processing circuit CSC, a horizontal drive circuit HDC, an output circuit OUT, a control circuit COC, and an input/output terminal IN.

The pixel region PA is disposed in a middle portion of the substrate 100. In the pixel region PA, a plurality of pixels 10 is arrayed in matrix in each of the arrow-X direction and the arrow-Y direction.

The pixel 10 includes an unillustrated photoelectric conversion element that converts light into electric charge, and an unillustrated plurality of transistors that processes converted electric charge into an electric signal.

The photoelectric conversion element is configured by a photodiode, for example.

The plurality of transistors includes at least a transfer transistor, a selection transistor, a reset transistor, and an amplification transistor, for example. The selection transistor, the reset transistor, and the amplification transistor construct a pixel circuit. The transfer transistor transfers electric charge converted from light in the photoelectric conversion element to the pixel circuit.

The plurality of transistors is configured by an insulated gate field effect transistor (IGFET). The IGFET includes at least a metal-oxide film-semiconductor field-effect transistor (MOSFET) and a metal-insulator-semiconductor field-effect transistor (MISFET).

It is to be noted that a shared pixel structure may be employed for the pixel 10. Here, the shared pixel structure is a structure in which the photoelectric conversion element as well as a plurality of transfer transistors of the plurality of pixels 10 and one pixel circuit to be shared are coupled to each other by a common floating diffusion (floating diffusion region). That is, the shared pixel structure is a structure in which the one pixel circuit is shared by the plurality of pixels 10.

The vertical drive circuit VDC, the column signal processing circuit CSC, the horizontal drive circuit HDC, the output circuit OUT, and the control circuit COC are disposed in a peripheral portion of the substrate 100 to construct a peripheral circuit of the solid-state imaging device 1.

In the control circuit COC, first, an input clock signal is inputted, and information commanding an operation mode or the like is received. In addition, in the control circuit COC, internally generated information is outputted.

That is, the control circuit COC generates a clock signal and a control signal that serve as standards of operations of the vertical drive circuit VDC, the column signal processing circuit CSC, and the horizontal drive circuit HDC on the basis of a vertical synchronization signal, a horizontal synchronization signal, and a master clock signal. The control circuit COC then outputs the generated clock signal and control signal to the vertical drive circuit VDC, the column signal processing circuit CSC, the horizontal drive circuit, and the like.

The vertical drive circuit VDC is constructed by a shift register, for example. In the vertical drive circuit VDC, predetermined pixel drive wiring Ld among a plurality of pieces of pixel drive wiring Ld is selected, and the selected pixel drive wiring Ld is supplied with a pulse that drives the pixel 10. The pixel 10 is driven on a row-by-row basis.

That is, in the vertical drive circuit VDC, the pixels 10 of the pixel region PA are sequentially selected and scanned in a vertical direction on a row-by-row basis. In each of the selected and scanned pixels 10, a pixel signal based on electric charge generated in response to a received light amount in the photoelectric conversion element is transmitted to a vertical signal line Lv. The pixel signal is then supplied to the column signal processing circuit CSC.

A plurality of column signal processing circuits CSC is arranged for each column of the pixels 10. The column signal processing circuit CSC performs signal processing such as noise removal on pixel signals outputted from the pixels 10 in one row, for each column of the pixels 10. For example, the column signal processing circuit CSC performs signal processing such as an analog-to-digital (AD: Analog Digital) conversion processing and correlated double sampling (CDS: Correlated Double Sampling) processing to remove a fixed pattern noise unique to the pixel 10.

The horizontal drive circuit HDC is constructed by a shift register, for example. In the horizontal drive circuit HDC, horizontal scanning pulses are sequentially outputted, and the respective column signal processing circuits CSC are sequentially selected. When the column signal processing circuit CSC is selected, a pixel signal is outputted from the column signal processing circuit CSC to a horizontal signal line Lh.

The output circuit OUT performs signal processing on image signals sequentially supplied from the respective column signal processing circuits CSC through the horizontal signal line Lh, and outputs the pixel signal having been subjected to the signal processing to the outside of the solid-state imaging device 1. The output circuit OUT performs buffering, for example. In addition, the output circuit OUT may further perform various types of digital signal processing such as black-level adjustment or column dispersion correction, in some cases.

The input/output terminal IN transmits and receives signals between the outside and the inside of the solid-state imaging device 1.

The solid-state imaging device 1 according to the first embodiment configured as described above is a CMOS (Complemental Metal Oxide Semiconductor) image sensor which is called a column AD system. That is, in the solid-state imaging device 1, the column signal processing circuit CSC that performs the CDS processing and the AD conversion processing is arranged for each column of the pixels.

### (2) Configuration of Pixel 10

FIG. 1 illustrates an example of a longitudinal cross-sectional configuration of the plurality of pixels 10 arrayed in the pixel region PA of the solid-state imaging device 1.

The pixel 10 includes a photoelectric conversion element 101, as a light-receiving element, that converts incident light into electric charge. A color filter 2 and an optical lens 6 are disposed at a position corresponding to the pixel 10. In addition, an inter-filter partition wall 3 and an inter-lens partition wall 5 are disposed at a corresponding position between the pixels 10.

Further, the solid-state imaging device 1 according to the first embodiment includes a protective film 4 for the color filter 2.

### (3) Configuration of Photoelectric Conversion Element 101

As illustrated in FIG. 1, the photoelectric conversion element 101 is disposed in the substrate 100, as viewed in the arrow-Y direction (hereinafter, simply referred to as “in a side view”). The photoelectric conversion element 101 is disposed for each of the pixels 10. The photoelectric conversion element 101 is configured by a photodiode (Photo Diode) formed at a p-n junction between a p-type semiconductor region and an n-type semiconductor region with no reference numerals.

Here, unillustrated wiring, circuit, or the like is disposed, on a side opposite to the arrow-Z direction, below the photoelectric conversion element 101 of the substrate 100. As the circuit, for example, there are disposed a drive circuit that drives the photoelectric conversion element 101, a readout circuit that reads a signal (electric charge) from the photoelectric conversion element 101, a signal processing circuit that processes a signal, the control circuit COC that controls various circuits (see FIG. 2), and the like.

### (4) Configuration of Color Filter 2

The color filter 2 is disposed above the substrate 100 in the arrow-Z direction at a position corresponding to the pixel 10. To describe this in more detail, the color filter 2 is formed over the substrate 100 with a protective film 102 interposed therebetween. For example, a silicon oxide (SiO₂) film may be used as the protective film 102.

In the first embodiment, the color filter 2 includes a first color filter 2A and a second color filter 2B. Although illustration is omitted here, the color filter 2 further includes a third color filter 2C, as illustrated in FIG. 32. That is, the color filter 2 includes the first color filter 2A, the second color filter 2B, and the third color filter 2C, which correspond to three primary colors of light.

Here, the first color filter 2A is a color filter having a green color, for example, as a first color.

The second color filter 2B is a color filter having a red color, for example, as a second color that differs from the first color. A transmitted wavelength of the light of the second color filter 2B is longer than a transmitted wavelength of the light of the first color filter 2A.

In addition, the third color filter 2C is a color filter having a blue color, for example, as a third color that differs from the first color and the second color. A transmitted wavelength of the light of the third color filter 2C is shorter than the wavelength of the light of the first color filter 2A, in a manner converse to the color filter 2B.

The color filter 2 is formed by a resin material to which, for example, an organic pigment is added. An acrylic-based resin, a styrene-based resin, or the like may be used as the resin material. In addition, in the first embodiment, the color filter 2 is formed to have a thickness of 400 nm or more and 600 nm or less, for example.

### (5) Configuration of Inter-Filter Partition Wall 3

The inter-filter partition wall 3 is disposed as an inter-waveguide light-blocking wall between the color filters 2. The inter-filter partition wall 3 has a light transmittance lower than a light transmittance of each of the color filter 2 and the optical lens 6, and further has a light-blocking property. The inter-filter partition wall 3 effectively suppresses or prevents light leakage to adjacent pixels 10.

Here, the inter-filter partition wall 3 includes a light-blocking film 31 and a low refractive index film 32.

The light-blocking film 31 is formed by a resin film or a metal film having a light-blocking property to light. For example, for the light-blocking film 31, there may be used a metal film selected from tungsten (W), aluminum (Al), copper (Cu), and the like, or a metal oxide film thereof. In addition, for the light-blocking film 31, there may be used an organic resin material to which a carbon black pigment, a titanium black pigment, or the like is added. Further, the light-blocking film 31 may be formed by stacking a plurality of metal films of different types, for example. Specifically, the light-blocking film 31 may be formed by stacking a titanium (Ti) film on a W film.

The low refractive index film 32 is stacked on the light-blocking film 31. The low refractive index film 32 has a refractive index lower than a refractive index of the light-blocking film 31. For the low refractive index film 32, for example, there may be used an inorganic material such as silicon nitride (SiN), SiO₂, or silicon oxynitride (SiON). In addition, for the low refractive index film 32, for example, there may be used an organic resin material such as a styrene-based resin, an acrylic-based resin, a styrene-acrylic copolymer-based resin, or a siloxane-based resin.

Further, in the first embodiment, a side surface and a top surface of the inter-filter partition wall 3 are covered with the protective film 102, and the inter-filter partition wall 3 is constructed to include the protective film 102.

### (6) Configuration of Optical Lens 6

The optical lens 6 is stacked above the color filter 2. The optical lens 6 includes a lens main body 61 and an antireflection film 62 formed on a surface of the lens main body 61. The lens main body 61 is formed in a curved shape protruding in the arrow-Z direction for each of the pixels 10 in a side view. The lens main body 61 is formed by a resin material having light transmissivity, for example.

In the pixel region PA illustrated in FIG. 2, the optical lens 6 disposed in each of positions corresponding to the pixels 10 is linked to another adjacent optical lens 6, and integrally formed, as illustrated in FIG. 1. The optical lens 6 is configured as an on-chip lens.

### (7) Configuration of Inter-Lens Partition Wall 5

The inter-lens partition wall 5 is disposed above the inter-filter partition wall 3 at a corresponding position between the pixels 10. In a plan view, an arrangement position of the inter-lens partition wall 5 is coincident with an arrangement position of the inter-filter partition wall 3, and the inter-lens partition wall 5 is arranged to overlap the inter-filter partition wall 3. In the first embodiment, the inter-lens partition wall 5 is disposed across the entire region around a side surface of the optical lens 6.

In addition, in a side view, a cross-section of the inter-lens partition wall 5 is formed in a rectangular shape in which a width dimension of a bottom part on a side of the color filter 2 and a width dimension of an upper part on a side of light incidence L are the same as each other. Specifically, the cross-section of the inter-lens partition wall 5 is formed in a rectangle shape in which a height dimension in the arrow-Z direction is larger than the width dimension. The inter-lens partition wall 5 effectively suppresses or prevents light leakage to adjacent pixels 10.

The inter-lens partition wall 5 is formed by, for example, an inorganic material such as SiO₂, or by an organic resin-based material having high light transmissivity such as a styrene-based resin, an acrylic-based resin, a styrene-acrylic copolymer-based resin, or a siloxane-based resin.

### (8) Configuration of Protective Film 4

As illustrated in FIG. 1, the protective film 4 is stacked on the color filter 2 between the color filter 2 and the inter-lens partition wall 5. To describe this in more detail, the protective film 4 is formed in contact with a surface of the color filter 2 at a position corresponding to the pixel 10. In addition, the protective film 4 is formed between the color filter 2 and the inter-lens partition wall 5 also at a corresponding position between the pixels 10. The protective film 4 protects the color filter 2 upon construction of the inter-lens partition wall 5, thus effectively suppressing or preventing damage to the color filter 2.

The protective film 4 is formed by one or more materials selected from a resin material and an inorganic material having light transmissivity for incident light in the arrow-Z direction and having etching selectivity with respect to the inter-lens partition wall 5 in a manufacturing method of the solid-state imaging device 1. The protective film 4 is formed using an SiO₂ film, for example. In addition, for the protective film 4, there may be used a photosensitive resin material as the resin material.

As for the etching selectivity, in other words, the protective film 4 is formed as an etching stopper film upon etching working of the inter-lens partition wall 5.

A thickness t1 of the protective film 4 in the arrow-Z direction is formed to be thinner than a thickness t2 of the inter-lens partition wall 5 in the same direction. Specifically, the thickness t1 of the protective film 4 is set to 50 nm or more and 200 nm or less, for example.

Further, the protective film 4 has a refractive index that sequentially decreases in a path of incident light L from the optical lens 6 to the color filter 2, thus reducing transmission loss of light.

As an example, a refractive index of the protective film 4 is set to 1.5 or more and 1.8 or less, for example. In addition, a refractive index of the above-described color filter 2 is set to 1.6 or more and 2.0 or less, for example. A refractive index of the optical lens 6 is set to 1.5 or more and 2.0 or less, for example. A refractive index of the inter-lens partition wall 5 is set to 1.1 or more and less than 1.5, for example.

That is, the magnitudes of the respective refractive indexes of the color filter 2, the protective film 4, the optical lens 6, and the inter-lens partition wall 5 are set to be in a relationship of the following expression.

Color Filter 2>Protective Film 4>Optical Lens 6>Inter-Lens Partition Wall 5

### [Manufacturing Method of Solid-State Imaging Device 1]

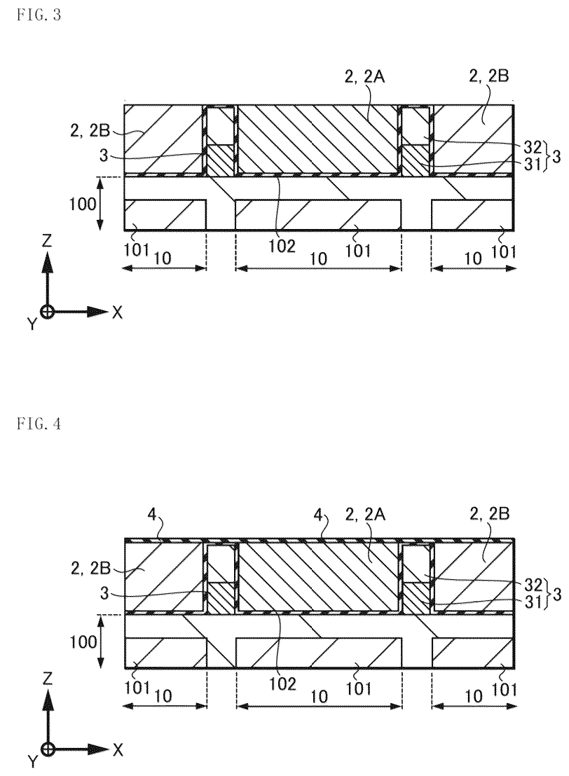

FIGS. 3 to 9 are each an explanatory step cross-sectional view of the manufacturing method of the solid-state imaging device 1 according to the first embodiment. The manufacturing method of the solid-state imaging device 1 is as follows.

First, the photoelectric conversion element 101 is formed in the substrate 100 to form the pixel 10 (see FIG. 1). Thereafter, as illustrated in FIG. 3, the color filter 2 is formed at a position corresponding to the pixel 10, and the inter-filter partition wall 3 is formed at a corresponding position between the pixels 10.

As illustrated in FIG. 4, the protective film 4 is formed across the entire surface on the color filter 2 and the inter-filter partition wall 3.

When a resin material is used for the protective film 4, the protective film 4 is formed by a spin-coating method, for example. In addition, when an inorganic material is used for the protective film 4, the protective film 4 is formed by, for example, a spin-coating method, a chemical vapor deposition (CVD: Chemical Vapor Deposition) method, or a sputtering method.

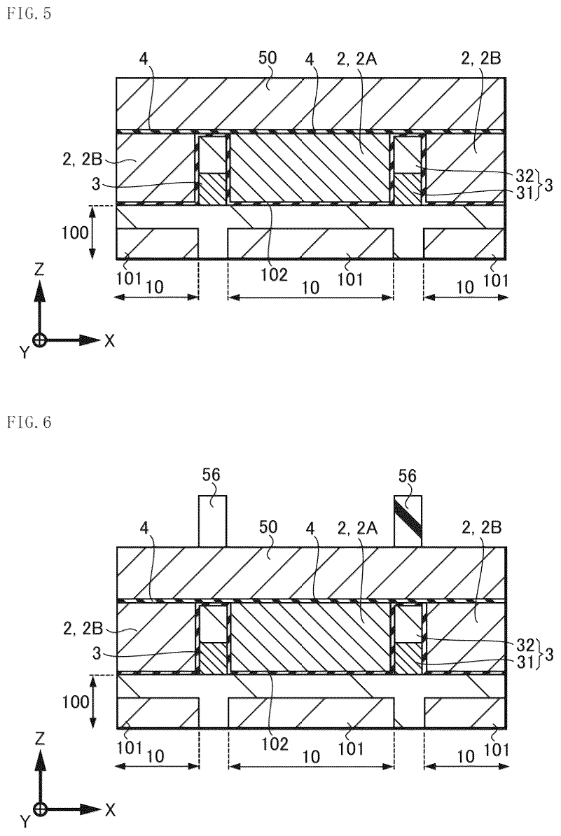

As illustrated in FIG. 5, a partition wall formation layer 50 is formed across the entire surface on the protective film 4. The partition wall formation layer 50 forms the inter-lens partition wall 5. As described above, an inorganic material or a resin material is used for the partition wall formation layer 50. Therefore, the partition wall formation layer 50 is formed by a spin-coating method, a CVD method, or the like.

As illustrated in FIG. 6, a mask 56 is formed on the partition wall formation layer 50 at a corresponding position between the pixels 10. The mask 56 is formed by a photolithography technique, for example.

The mask 56 is used to remove the partition wall formation layer 50 on the color filter 2, and the inter-lens partition wall 5 is formed by the partition wall formation layer 50 remaining below the mask 56 (see FIG. 7). That is, the inter-lens partition wall 5 is formed on the inter-filter partition wall 3 at a corresponding position between the pixels 10. Dry etching is used here to remove the partition wall formation layer 50.

As described above, the protective film 4 has etching selectivity with respect to the inter-filter partition wall 3. Therefore, upon formation of the inter-filter partition wall 3, the protective film 4 is used as an etching stopper film for dry etching. The partition wall formation layer 50 is removed until a front surface of the protective film 4 is exposed, and the surface of the color filter 2 is not exposed. Accordingly, the color filter 2 is protected by the protective film 4, and thus the surface of the color filter 2 is not damaged without being etched by dry etching.

After the formation of the inter-lens partition wall 5, the mask 56 is removed, as illustrated in FIG. 7.

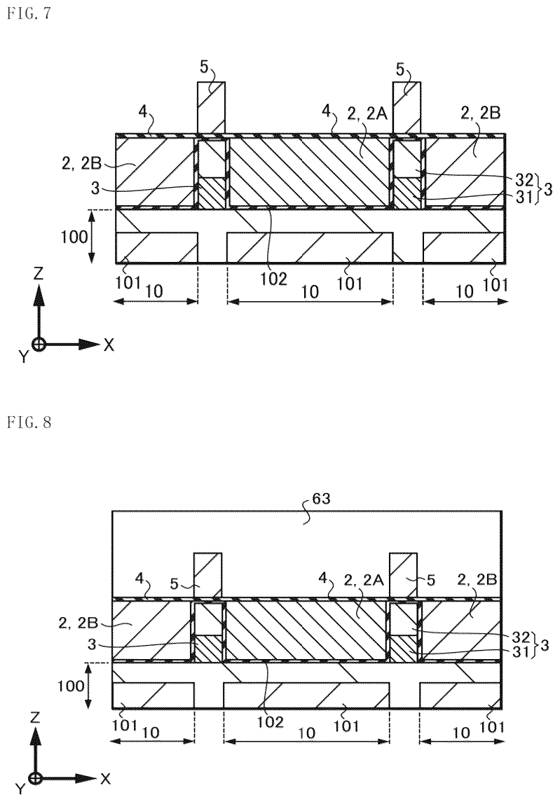

As illustrated in FIG. 8, there is formed, on the protective film 4 and on the inter-lens partition wall 5, a lens formation layer 63 in which these protective film 4 and inter-lens partition wall 5 are embedded. The lens formation layer 63 is formed by a spin-coating method, for example, using a resin material.

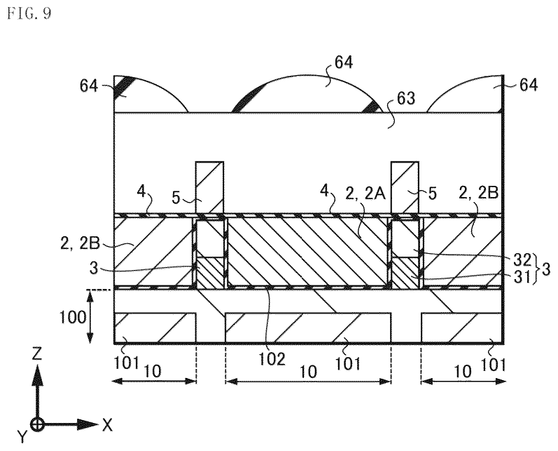

As illustrated in FIG. 9, a mask 64 is formed on the lens formation layer 63. The mask 64 is formed into a lens shape, for example, by forming a photoresist film, then performing patterning remaining at a position corresponding to the pixel 10, and thereafter performing reflow processing.

The mask 64 is used to perform patterning on the lens formation layer 63, and the lens main body 61 is formed from the lens formation layer 63. For example, an etch-back method is used for the patterning.

Here, in the manufacturing method of the solid-state imaging device 1 according to the first embodiment, the mask 64 is used to form the lens main body 61. In the present technology, the lens formation layer 63 may be patterned without using the mask 64 described above, and then the lens formation layer 63 may be subjected to reflow processing to form the lens main body 61.

After the formation of the lens main body 61, the antireflection film 62 is formed on the lens main body 61, as illustrated in FIG. 1 mentioned above. When the series of manufacturing steps ends, the solid-state imaging device 1 according to the first embodiment is completed.

### [Workings and Effects]

As illustrated in FIG. 1, the solid-state imaging device 1 according to the first embodiment includes the color filter 2, the optical lens 6, and the inter-lens partition wall 5. The color filter 2 is disposed at a position corresponding to a pixel. The optical lens 6 is stacked on the color filter 2. The inter-lens partition wall 5 is disposed around the side surface of the optical lens 6 at a corresponding position between the pixels 10. Here, the inter-lens partition wall 5 is disposed across the entire region around the side surface of the optical lens 6.

Here, the solid-state imaging device 1 further includes the protective film 4. The protective film 4 is stacked on the color filter 2 between the color filter 2 and the inter-lens partition wall 5.

It is therefore possible, in the solid-state imaging device 1, to coat the color filter 2 and to protect the color filter 2. To describe this in more detail, upon the construction of the inter-lens partition wall 5, the protective film 4 protects the surface of the color filter 2, thus enabling the protective film 4 to effectively suppress or prevent damage to the surface of the color filter 2.

That is, in the manufacturing method of the solid-state imaging device 1, as illustrated in FIGS. 6 and 7, the protective film 4 has etching selectivity with respect to the inter-lens partition wall 5, and is used as an etching stopper film. It is therefore possible to effectively suppress or prevent, during the manufacturing, dust adherence or contamination inside an etching apparatus caused by damage to the color filter 2. In addition, it is possible to effectively suppress variations in an etching rate caused by the dust adherence or the contamination for each wafer (semiconductor wafer) by which the solid-state imaging device 1 is manufactured.

In addition, in the solid-state imaging device 1, as illustrated in FIG. 1, the thickness t1 of the protective film 4 is thinner than the thickness t2 of the inter-lens partition wall 5. The thickness t2 of the inter-lens partition wall 5 is substantially equal to the thickness of the color filter 2, and thus, consequently, the thickness t1 of the protective film 4 is thinner than the thickness of the color filter 2.

This makes it possible to virtually eliminate transmission loss of light caused by the protective film 4. That is, the transmission loss of light is not affected, thus making it possible to effectively suppress or prevent damage to the color filter 2.

In addition, in the solid-state imaging device 1 or in the manufacturing method of the solid-state imaging device 1, as illustrated in FIG. 1 or 7, the protective film 4 has etching selectivity with respect to the inter-lens partition wall 5. In other words, the protective film 4 is formed as an etching stopper film upon etching working of the inter-lens partition wall 5. That is, when the inter-lens partition wall 5 is worked by dry etching, the protective film 4 protects the surface of the color filter 2. The protective film 4 is formed by one or more materials selected from resin materials and inorganic materials.

This enables the protective film 4 to effectively suppress or prevent damage to the surface of the color filter 2.

In addition, in the solid-state imaging device 1, as illustrated in FIG. 1, the refractive index of the protective film 4 is 1.5 or more and 1.8 or less. Meanwhile, the refractive index of the color filter 2 is 1.6 or more and 2.0 or less. In addition, the refractive index of the optical lens 6 is 1.5 or more and 2.0 or less. Further, the refractive index of the inter-lens partition wall 5 is 1.1 or more and less than 1.5.

That is, the magnitudes of the respective refractive indexes of the color filter 2, the protective film 4, the optical lens 6, and the inter-lens partition wall 5 are in a relationship of the following expression.

Color Filter 2>Protective Film 4>Optical Lens 6>Inter-Lens Partition Wall 5

In the solid-state imaging device 1 configured as described above, the protective film 4 has a refractive index that increases sequentially in the path of the incident light L from the optical lens 6 to the color filter 2. This makes it possible to reduce the transmission loss of the incident light L while allowing the protective film 4 to effectively suppress or prevent damage to the color filter 2.

### 2. Second Embodiment

Next, description is given of the solid-state imaging device 1 according to the second embodiment of the present disclosure. In the second embodiment and the subsequent embodiments, components the same or substantially the same as the components of the solid-state imaging device 1 according to the first embodiment are denoted by the same reference numerals, and redundant descriptions are omitted.

### [Configuration of Solid-State Imaging Device 1]

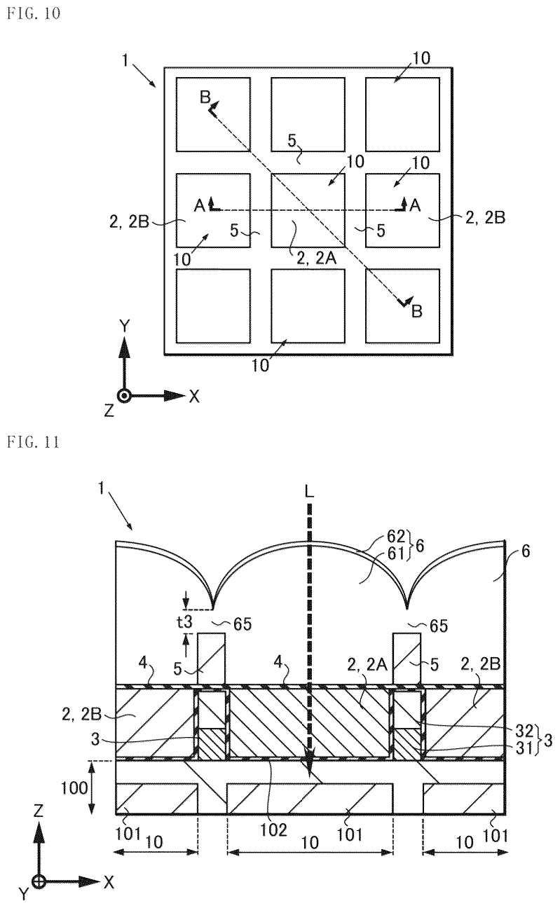

FIG. 10 illustrates an example of a planar configuration of the plurality of pixels 10 arrayed in the pixel region PA of the solid-state imaging device 1. FIG. 11 illustrates an example of a longitudinal cross-sectional configuration of the pixels 10 taken along a section line A-A illustrated in FIG. 10. FIG. 12 illustrates an example of a longitudinal cross-sectional configuration of the pixels 10 taken along a section line B-B illustrated in FIG. 10.

As illustrated in FIGS. 10 to 12, in the solid-state imaging device 1 according to the second embodiment, the inter-lens partition wall 5 is extended in the arrow-X direction, disposed in the arrow-Y direction at a constant interval, further extended in the arrow-Y direction, and disposed in the arrow-X direction at a constant interval. That is, the inter-lens partition wall 5 is formed in a lattice pattern in a plan view. The inter-lens partition wall 5 is disposed along the entire region around the side surface of a bottom part of the optical lens 6 that is formed in a curved shape for each of the pixels 10.

As illustrated in FIG. 11, on the inter-lens partition wall 5 between the pixels 10 adjacent to each other in the arrow-X direction, a thickness t3 of a linking site 65 in the arrow-Z direction between the optical lenses 6 adjacent to each other in the same direction becomes thick. Although illustration is omitted, on the inter-lens partition wall 5 between the pixels 10 adjacent to each other in the arrow-Y direction, a thickness of the linking site 65 in the arrow-Z direction between the optical lenses 6 adjacent to each other in the same direction becomes thick in the same manner as the thickness t3.

Meanwhile, as illustrated in FIG. 12, on the inter-lens partition wall 5 between the pixels 10 adjacent to each other in a diagonal direction relative to the arrow-X direction or the arrow-Y direction, a thickness t4 of a linking site 66 in the arrow-Z direction between the optical lenses 6 adjacent to each other in the same direction becomes thinner than the thickness t3. The term “inter-lens partition wall 5 between the pixels 10 adjacent to each other in the diagonal direction” is used to mean the inter-lens partition wall 5 at an intersecting position between the inter-lens partition wall 5 extending in the arrow-X direction and the inter-lens partition wall 5 extending in the arrow-Y direction. In addition, the thickness t4 may be zero with no linking site 66 being present.

Components other than those described above are the same or substantially the same as the components of the solid-state imaging device 1 according to the first embodiment. In addition, the manufacturing methods of the solid-state imaging device 1 according to the second embodiment and embodiments subsequent to the second embodiments are basically similar to the manufacturing method of the solid-state imaging device 1 according to the first embodiment, and therefore descriptions thereof are omitted.

### [Workings and Effects]

In the solid-state imaging device 1 according to the second embodiment, it is possible to obtain workings and effects similar to the workings and effects obtained by the solid-state imaging device 1 according to the first embodiment.

In addition, in the solid-state imaging device 1, as illustrated in FIGS. 10 to 12, the respective thicknesses of the linking site 65 and the linking site 66 of the optical lens 6 at a corresponding position between adjacent pixels 10 are appropriately set. This makes it possible to improve flexibility of the construction of each of the inter-lens partition wall 5 and the optical lens 6. For example, the respective thicknesses of the linking site 65 and the linking site 66 of the optical lens 6 may be appropriately set, thus making it possible to appropriately set one or more selected from the thickness of the inter-lens partition wall 5 (height thereof in the arrow-Z direction), the width thereof (width thereof in the arrow-X direction or the arrow-Y direction), and the material thereof.

### Modification Example

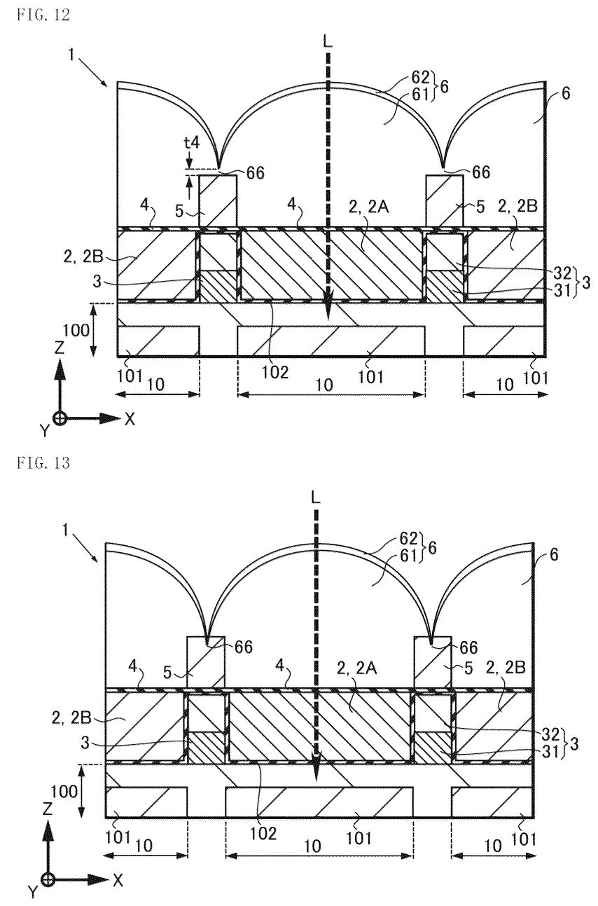

Next, description is given of the solid-state imaging device 1 according to a modification example of the second embodiment. FIG. 13 illustrates an example of a longitudinal cross-sectional configuration of the pixels 10 taken along at a position corresponding to the section line B-B illustrated in FIG. 10.

As illustrated in FIG. 13, in the solid-state imaging device 1 according to the modification example, the linking site 66 of the optical lens 6 is formed to protrude to a side opposite to a top surface of the inter-lens partition wall 5 in the arrow-Z direction. That is, the linking site 66 is formed in such a shape as to bite into an upper part of the inter-lens partition wall 5.

Components other than those described above are the same or substantially the same as the components of the solid-state imaging device 1 according to the second embodiment.

In the solid-state imaging device 1 according to the modification example of the second embodiment, it is possible to obtain workings and effects similar to the workings and effects obtained by the solid-state imaging device 1 according to the second embodiment.

### 3. Third Embodiment

Next, description is given of the solid-state imaging device 1 according to the third embodiment of the present disclosure.

### [Configuration of Solid-State Imaging Device 1]

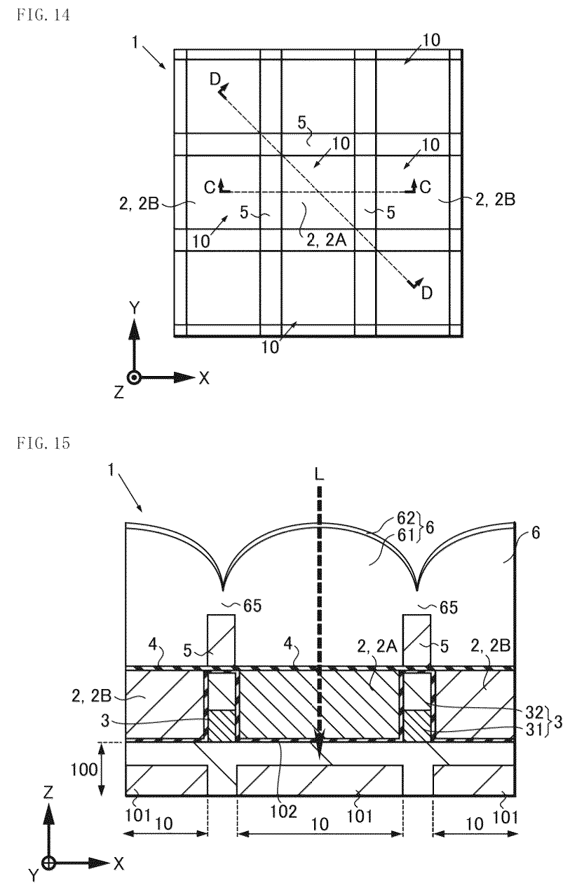

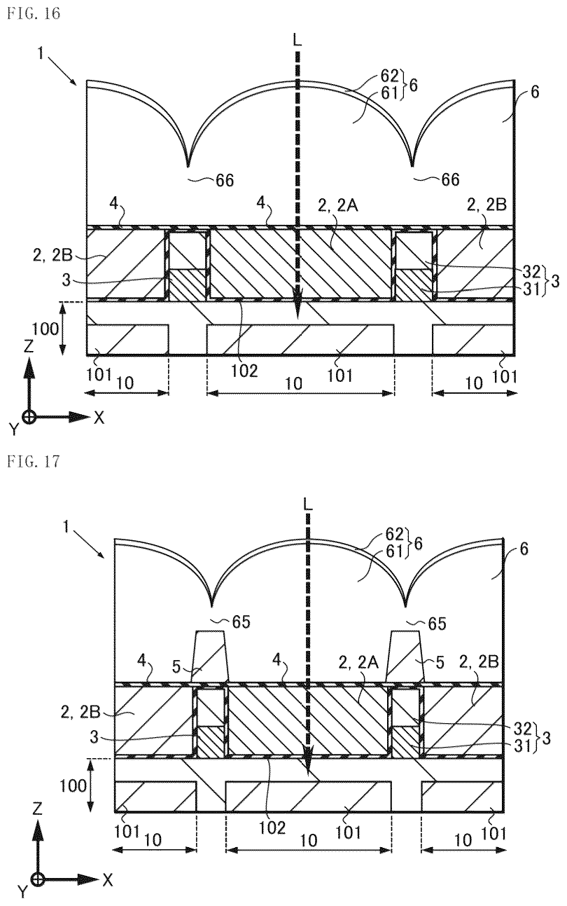

FIG. 14 illustrates an example of a planar configuration of the plurality of pixels 10 arrayed in the pixel region PA of the solid-state imaging device 1. FIG. 15 illustrates an example of a longitudinal cross-sectional configuration of the pixels 10 taken along a section line C-C illustrated in FIG. 14. FIG. 16 illustrates an example of a longitudinal cross-sectional configuration of the pixels 10 taken along a section line D-D illustrated in FIG. 14.

As illustrated in FIGS. 14 to 16, in the solid-state imaging device 1 according to the third embodiment, the structure of the inter-lens partition wall 5 of the solid-state imaging device 1 according to the second embodiment is changed.

To describe this in more detail, the inter-lens partition wall 5 is disposed at each corresponding position between the pixels 10 adjacent to each other in the arrow-X direction and between the pixels 10 adjacent to each other in the arrow-Y direction, and the inter-lens partition wall 5 is not disposed at a corresponding position between the pixels 10 adjacent to each other in the diagonal direction. That is, the inter-lens partition wall 5 is not disposed at an intersecting position between the inter-lens partition wall 5 extending in the arrow-X direction and the inter-lens partition wall 5 extending in the arrow-Y direction. In other words, the inter-lens partition wall 5 is disposed on at least a portion of a periphery of a side surface of the pixel 10.

A spacing dimension between the pixels 10 adjacent to each other in the diagonal direction is larger than a spacing dimension between the pixels 10 adjacent to each other in the arrow-X direction and a spacing dimension between the pixels 10 adjacent to each other in the arrow-Y direction. This reduces light leakage to the adjacent pixels 10 even when the inter-lens partition wall 5 is not disposed between the pixels 10 adjacent to each other in the diagonal direction.

Components other than those described above are the same or substantially the same as the components of the solid-state imaging device 1 according to the second embodiment.

### [Workings and Effects]

In the solid-state imaging device 1 according to the third embodiment, it is possible to obtain workings and effects similar to the workings and effects obtained by the solid-state imaging device 1 according to the second embodiment.

### 4. Fourth Embodiment

Next, description is given of the solid-state imaging device 1 according to the fourth embodiment of the present disclosure.

### [Configuration of Solid-State Imaging Device 1]

FIG. 17 illustrates an example of a longitudinal cross-sectional configuration of the plurality of pixels 10 arrayed in the pixel region PA of the solid-state imaging device 1.

As illustrated in FIG. 17, in the solid-state imaging device 1 according to the fourth embodiment, the structure of the inter-lens partition wall 5 of the solid-state imaging device 1 according to the first embodiment is changed.

To describe this in more detail, a width dimension of the inter-lens partition wall 5 at a lower part is larger than a width dimension thereof at the upper part in the arrow-Z direction. Here, in a side view, the inter-lens partition wall 5 is formed in a trapezoidal shape.

In addition, although illustration is omitted, the cross-section of the inter-lens partition wall 5 may be formed in a staircase shape in which the width dimension thereof is gradually reduced as being toward the upper part from the lower part.

Components other than those described above are the same or substantially the same as the components of the solid-state imaging device 1 according to the first embodiment.

### [Workings and Effects]

In the solid-state imaging device 1 according to the fourth embodiment, it is possible to obtain workings and effects similar to the workings and effects obtained by the solid-state imaging device 1 according to the first embodiment.

### 5. Fifth Embodiment

Next, description is given of the solid-state imaging device 1 according to the fifth embodiment of the present disclosure.

### [Configuration of Solid-State Imaging Device 1]

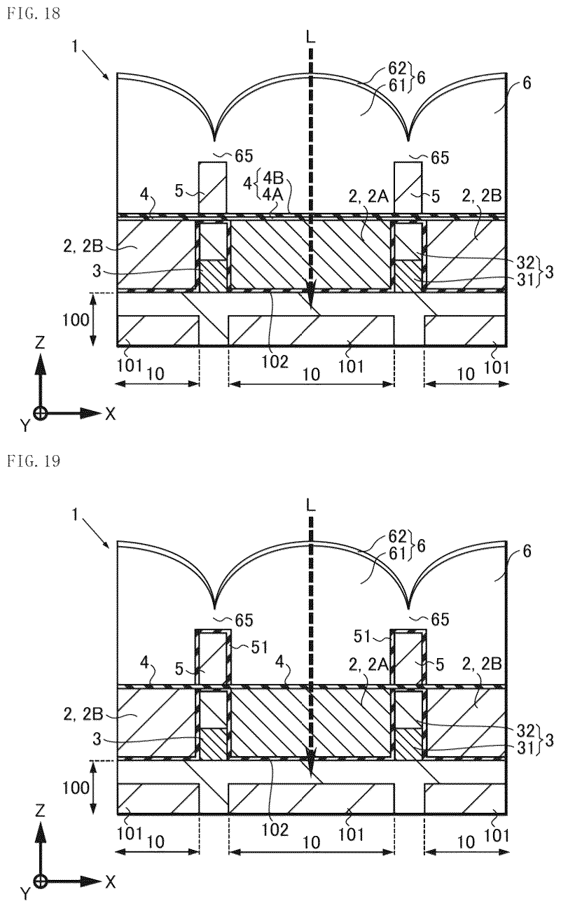

FIG. 18 illustrates an example of a longitudinal cross-sectional configuration of the plurality of pixels 10 arrayed in the pixel region PA of the solid-state imaging device 1.

As illustrated in FIG. 18, in the solid-state imaging device 1 according to the fifth embodiment, the structure of the protective film 4 of the solid-state imaging device 1 according to the first embodiment is changed.

To describe this in more detail, the protective film 4 is formed by a plurality of layers stacked in a film thickness direction that is the arrow-Z direction. Here, the protective film 4 has a two-layer structure of a first layer 4A formed on a side of the color filter 2 and a second layer 4B stacked on the first layer 4A and formed on a side of the optical lens 6.

It is possible for the first layer 4A to have a smaller step difference due to a difference in the thickness of the color filter 2 than the second layer 4B. In addition, a refractive index of the first layer 4A is higher than a refractive index of the second layer 4B. The first layer 4A is formed by a resin material, for example. A thickness of the first layer 4A is 50 nm or more and 200 nm or less, for example.

Meanwhile, the second layer 4B is formed by an inorganic material, for example. A thickness of the second layer 4B is 10 nm or more and 200 nm or less, for example.

Components other than those described above are the same or substantially the same as the components of the solid-state imaging device 1 according to the first embodiment.

### [Workings and Effects]

In the solid-state imaging device 1 according to the fifth embodiment, it is possible to obtain workings and effects similar to the workings and effects obtained by the solid-state imaging device 1 according to the first embodiment.

In addition, in the solid-state imaging device 1 according to the fifth embodiment, as illustrated in FIG. 18, among the plurality of layers of the protective film 4, the first layer 4A on the side of the color filter 2 has a smaller step difference due to the difference in the thickness of the color filter 2 than the second layer 4B on the side of the optical lens 6.

This allows the first layer 4A of the protective film 4 to absorb the step difference of the color filter 2 due to color difference, thus making it possible to planarize the front surface of the protective film 4. This makes it possible to improve working accuracy of the optical lens 6 stacked on the protective film 4, for example.

In addition, in the solid-state imaging device 1, the refractive index of the first layer 4A on the side of the color filter 2, among the plurality of layers of the protective film 4, is higher than the refractive index of the second layer 4B on the side of the optical lens 6. That is, the protective film 4 has a refractive index that increases sequentially in the path of the incident light L along a thickness direction. This makes it possible to reduce the transmission loss of the incident light L while allowing the protective film 4 to effectively suppress or prevent damage to the color filter 2.

The workings and effects described above are achievable by forming the first layer 4A of the protective film 4 using a resin material, for example, and by forming the second layer 4B using an inorganic material, for example.

It is to be noted that the protective film 4 may be constructed by stacking three or more layers.

### 6. Sixth Embodiment

Next, description is given of the solid-state imaging device 1 according to the sixth embodiment of the present disclosure.

### [Configuration of Solid-State Imaging Device 1]

FIG. 19 illustrates an example of a longitudinal cross-sectional configuration of the plurality of pixels 10 arrayed in the pixel region PA of the solid-state imaging device 1.

As illustrated in FIG. 19, in the solid-state imaging device 1 according to the sixth embodiment, the structure of the inter-lens partition wall 5 of the solid-state imaging device 1 according to the first embodiment is changed. To describe this in more detail, the entire surface of the inter-lens partition wall 5 including a side surface and the top surface is covered with a partition wall protective film 51. For the partition wall protective film 51, for example, there may be used an inorganic material such as SiO₂ or SiN.

Components other than those described above are the same or substantially the same as the components of the solid-state imaging device 1 according to the first embodiment.

### [Workings and Effects]

In the solid-state imaging device 1 according to the sixth embodiment, it is possible to obtain workings and effects similar to the workings and effects obtained by the solid-state imaging device 1 according to the first embodiment.

In addition, in the solid-state imaging device 1 according to the sixth embodiment, as illustrated in FIG. 19, the inter-lens partition wall 5 is covered with the partition wall protective film 51. This makes it possible to effectively suppress or prevent a composition component, specifically, a resin component of the optical lens 6, in particular, of the lens main body 61 being diffused to the inter-lens partition wall 5.

### 7. Seventh Embodiment

Next, description is given of the solid-state imaging device 1 according to the seventh embodiment of the present disclosure.

### [Configuration of Solid-State Imaging Device 1]

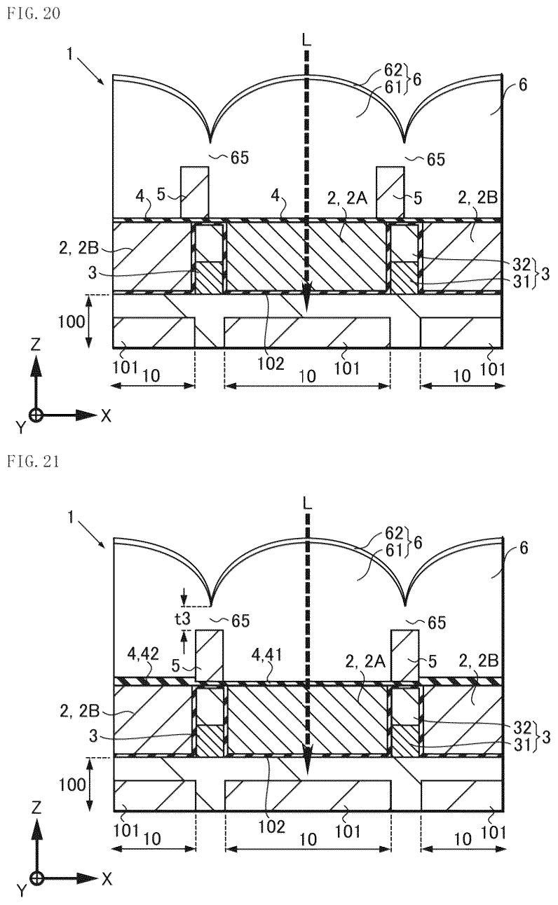

FIG. 20 illustrates an example of a longitudinal cross-sectional configuration of the plurality of pixels 10 arrayed in the pixel region PA of the solid-state imaging device 1.

As illustrated in FIG. 20, in the solid-state imaging device 1 according to the seventh embodiment, the structure of the inter-lens partition wall 5 of the solid-state imaging device 1 according to the first embodiment is changed.

To describe this in more detail, in at least a portion of the pixel region PA (see FIG. 2), a center position of the inter-lens partition wall 5 in the width direction is disposed offset in the arrow-X direction (or the arrow-Y direction) from a center position of the inter-filter partition wall 3 in the width direction. Specifically, in a middle portion of the pixel region PA, the inter-lens partition wall 5 is disposed at a position coincident with the inter-filter partition wall 3. Meanwhile, in a peripheral portion of the pixel region PA, the inter-lens partition wall 5 is disposed at a position offset from the inter-filter partition wall 3.

Components other than those described above are the same or substantially the same as the components of the solid-state imaging device 1 according to the first embodiment.

### [Workings and Effects]

In the solid-state imaging device 1 according to the seventh embodiment, it is possible to obtain workings and effects similar to the workings and effects obtained by the solid-state imaging device 1 according to the first embodiment.

In addition, in the solid-state imaging device 1 according to the seventh embodiment, as illustrated in FIG. 20, at least a portion of the inter-lens partition wall 5 is disposed at a position offset from the inter-filter partition wall 3 of the pixel region PA. At the position offset from the inter-lens partition wall 5, an incident angle of the incident light L on the pixel 10 is captured, thus enabling the incident light L to be increased. This makes it possible to effectively suppress output non-uniformity (shading) of the pixel region PA.

### 8. Eighth Embodiment

Next, description is given of the solid-state imaging device 1 according to the eighth embodiment of the present disclosure.

### [Configuration of Solid-State Imaging Device 1]

FIG. 21 illustrates an example of a longitudinal cross-sectional configuration of the plurality of pixels 10 arrayed in the pixel region PA of the solid-state imaging device 1.

As illustrated in FIG. 21, in the solid-state imaging device 1 according to the eighth embodiment, the structure of the protective film 4 of the solid-state imaging device 1 according to the first embodiment is changed.

To describe this in more detail, the color filter 2 includes the first color filter 2A, and the second color filter 2B having a longer transmitted wavelength of light than that of the first color filter 2A. As described above, here, the first color filter 2A is a green color filter, and the second color filter 2B is a red color filter.

Further, the first color filter 2A is provided with a first protective film 41 as the protective film 4. The second color filter 2B is provided with a second protective film 42 as the protective film 4. The second protective film 42 is formed to have a thickness that is thicker than a thickness of the first protective film 41. That is, the second protective film 42 is formed to have a thickness corresponding to a long transmitted wavelength of light.

The thickness of the first protective film 41 is 50 nm or more and 200 nm or less, for example. In addition, the thickness of the second protective film 42 is 50 nm or more and 200 nm or less, for example.

It is to be noted that although illustration is omitted, the color filter 2 further includes the third color filter 2C (see FIG. 32) having a shorter transmitted wavelength of light than that of the first color filter 2A. The third color filter 2C is a blue color filter.

The third color filter is provided with an unillustrated third protective film as the protective film 4. The third protective film is formed to have a thickness that is thinner than the thickness of the first protective film 41. The thickness of the third protective film is 50 nm or more and 200 nm or less, for example.

Components other than those described above are the same or substantially the same as the components of the solid-state imaging device 1 according to the first embodiment.

### [Workings and Effects]

In the solid-state imaging device 1 according to the eighth embodiment, it is possible to obtain workings and effects similar to the workings and effects obtained by the solid-state imaging device 1 according to the first embodiment.

In addition, in the solid-state imaging device 1 according to the eighth embodiment, as illustrated in FIG. 21, the color filter 2 includes the first color filter 2A, and the second color filter 2B having a longer transmitted wavelength of light than that of the first color filter 2A. Further, the first color filter 2A is provided with the first protective film 41. Additionally, the second color filter 2B is provided with the second protective film 42 having the thickness that is thicker than the thickness of the first protective film 41.

It is therefore possible to appropriately adjust the thickness of the protective film 4 in a manner to correspond to a transmitted wavelength of light of the color filter 2, thus making it possible to effectively suppress reflection at an interface part between the color filter 2 and the optical lens 6.

### 9. Ninth Embodiment

Next, description is given of the solid-state imaging device 1 according to the ninth embodiment of the present disclosure.

### [Configuration of Solid-State Imaging Device 1]

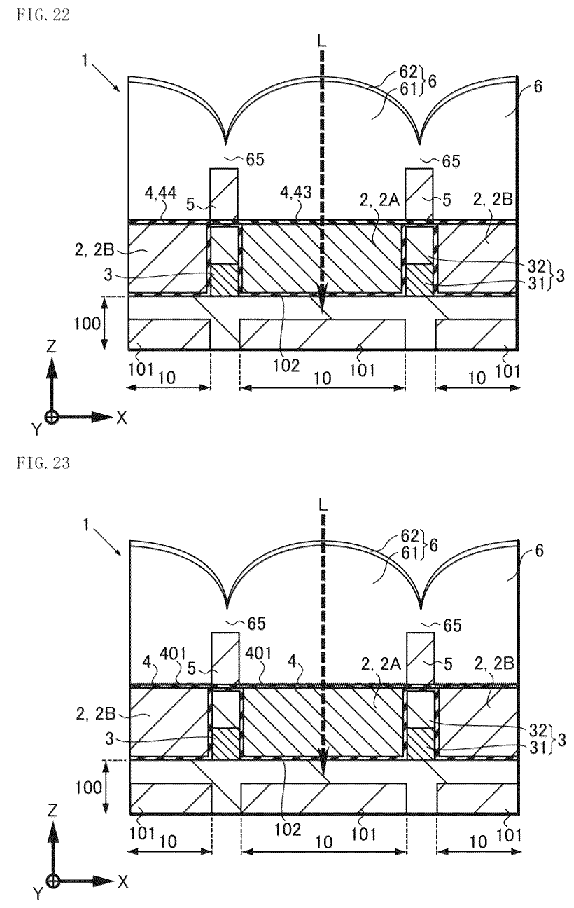

FIG. 22 illustrates an example of a longitudinal cross-sectional configuration of the plurality of pixels 10 arrayed in the pixel region PA of the solid-state imaging device 1.

As illustrated in FIG. 22, in the solid-state imaging device 1 according to the ninth embodiment, the structure of the protective film 4 of the solid-state imaging device 1 according to the first embodiment is changed.

To describe this in more detail, the color filter 2 includes the first color filter 2A, and the second color filter 2B having a longer transmitted wavelength of light than that of the first color filter 2A. As described above, here, the first color filter 2A is a green color filter, and the second color filter 2B is a red color filter.

Further, the first color filter 2A is provided with a first protective film 43 as the protective film 4. The second color filter 2B is provided with a second protective film 44 as the protective film 4. The second protective film 44 has a refractive index that is higher than a refractive index of the first protective film 43. That is, the second protective film 44 is formed to have a refractive index corresponding to a long transmitted wavelength of light.

It is to be noted that, although illustration is omitted, the color filter 2 further includes the third color filter 2C (see FIG. 32) having a shorter transmitted wavelength of light than that of the first color filter 2A. The third color filter 2C is a blue color filter.

The third color filter 2C is provided with a third protective film as the protective film 4. The third protective film has a refractive index that is lower than the refractive index of the first protective film 43.

Components other than those described above are the same or substantially the same as the components of the solid-state imaging device 1 according to the first embodiment.

### [Workings and Effects]

In the solid-state imaging device 1 according to the ninth embodiment, it is possible to obtain workings and effects similar to the workings and effects obtained by the solid-state imaging device 1 according to the first embodiment.

In addition, in the solid-state imaging device 1 according to the ninth embodiment, as illustrated in FIG. 22, the color filter 2 includes the first color filter 2A, and the second color filter 2B having a longer transmitted wavelength of light than that of the first color filter 2A. Further, the first color filter 2A is provided with the first protective film 43. Additionally, the second color filter 2B is provided with the second protective film 44 having a refractive index that is higher than the refractive index of the first protective film 43.

It is therefore possible to appropriately adjust the refractive index of the protective film 4 in a manner to correspond to the transmitted wavelength of light of the color filter 2, thus making it possible to effectively suppress reflection at the interface part between the color filter 2 and the optical lens 6.

It is to be noted that the solid-state imaging device 1 according to the ninth embodiment may be combined with the solid-state imaging device 1 according to the eighth embodiment. Specifically, it is possible to appropriately adjust both of the thickness and the refractive index of the protective film 4 in a manner to correspond to the transmitted wavelength of light of the color filter 2.

### 10. Tenth Embodiment

Next, description is given of the solid-state imaging device 1 according to the tenth embodiment of the present disclosure.

### [Configuration of Solid-State Imaging Device 1]

FIG. 23 illustrates an example of a longitudinal cross-sectional configuration of the plurality of pixels 10 arrayed in the pixel region PA of the solid-state imaging device 1.

As illustrated in FIG. 23, in the solid-state imaging device 1 according to the tenth embodiment, the structure of the protective film 4 of the solid-state imaging device 1 according to the first embodiment is changed.

To describe this in more detail, the front surface (corresponding to a “first surface” according to the present technology) of the protective film 4 on the side of the optical lens 6 is provided with an irregularity 401 that is larger than a back surface (corresponding to a “second surface” according to the present technology) on the side of the color filter 2. The back surface of the protective film 4 on the color filter 2 is substantially planar.

The irregularity 401 is formed to have a uniform size. It is to be noted that the irregularity 401 may be formed to have a non-uniform size. The size of the irregularity 401 is adjusted to 50 nm or more and 200 nm or less, for example, in the thickness direction. In other words, a surface roughness of the protective film 4 is adjusted, for example, to be within a range of the above-mentioned numerical values.

For example, the irregularity 401 is easily formable as follows.

First, in the manufacturing method of the solid-state imaging device 1 according to the first embodiment (hereinafter, simply referred to as a “first manufacturing method”), the protective film 4 is formed, as illustrated in FIG. 4 mentioned above. In the protective film 4, an additive having etching selectivity different from a main composition material is appropriately dispersed to the main composition material.

Further, as illustrated in FIG. 7 concerning the first manufacturing method, the protective film 4 is used as an etching stopper film to form the inter-lens partition wall 5. At this time, the front surface of the protective film 4 is slightly over-etched to allow etching of the main composition material to proceed in a region where no additive is present. In other words, the additive is used as a mask. This allows for formation of the irregularity 401 on the front surface of the protective film 4.

Components other than those described above are the same or substantially the same as the components of the solid-state imaging device 1 according to the first embodiment.

### [Workings and Effects]

In the solid-state imaging device 1 according to the tenth embodiment, it is possible to obtain workings and effects similar to the workings and effects obtained by the solid-state imaging device 1 according to the first embodiment.

In addition, as illustrated in FIG. 23, the solid-state imaging device 1 according to the tenth embodiment includes, on the front surface (first surface) of the protective film 4 on the side of the optical lens 6, the irregularity 401 that is larger than the back surface (second surface) on the side of the color filter 2. It is possible for the irregularity 401 of the protective film 4 to scatter reflected light for the incident light L and thus to reduce reflected light. This makes it possible, in the solid-state imaging device 1, to effectively suppress or prevent a flare phenomenon.

### 11. Eleventh Embodiment

Next, description is given of the solid-state imaging device 1 according to the eleventh embodiment of the present disclosure.

### [Configuration of Solid-State Imaging Device 1]

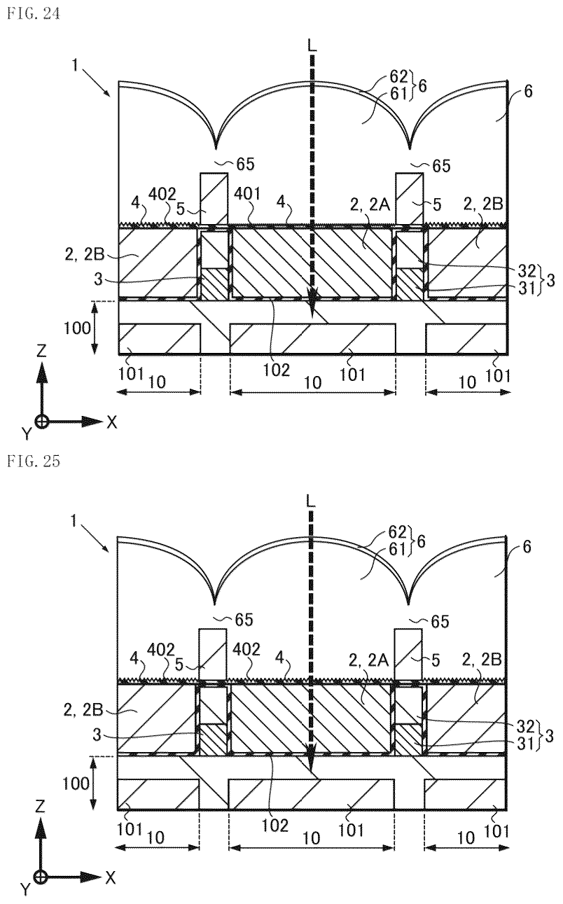

FIG. 24 illustrates an example of a longitudinal cross-sectional configuration of the plurality of pixels 10 arrayed in the pixel region PA of the solid-state imaging device 1.

As illustrated in FIG. 24, in the solid-state imaging device 1 according to the eleventh embodiment, the structure of the protective film 4 of the solid-state imaging device 1 according to the tenth embodiment is changed.

To describe this in more detail, the color filter 2 includes the first color filter 2A, and the second color filter 2B having a longer transmitted wavelength of light than that of the first color filter 2A. As described above, here, the first color filter 2A is a green color filter, and the second color filter 2B is a red color filter.

In addition, the first color filter 2A is provided with the protective film 4 having the irregularity 401. The second color filter 2B is provided with the protective film 4 having an irregularity 402 that is larger than the irregularity 401. In other words, a surface roughness of the irregularity 402 is greater than a surface roughness of the irregularity 401. Further, a density or a cycle of the irregularity 402 is larger than a density or a cycle of the irregularity 401.

It is to be noted that, although illustration is omitted, the color filter 2 further includes the third color filter 2C (see FIG. 32) having a shorter transmitted wavelength of light than that of the first color filter 2A. The third color filter 2C is a blue color filter.

The third color filter 2C is provided with the protective film 4 having an irregularity that is smaller than the irregularity 401.

Components other than those described above are the same or substantially the same as the components of the solid-state imaging device 1 according to the tenth embodiment.

### [Workings and Effects]

In the solid-state imaging device 1 according to the eleventh embodiment, it is possible to obtain workings and effects similar to the workings and effects obtained by the solid-state imaging device 1 according to the tenth embodiment.

In addition, in the solid-state imaging device 1 according to the eleventh embodiment, as illustrated in FIG. 24, the color filter 2 includes the first color filter 2A, and the second color filter 2B having a longer transmitted wavelength of light than that of the first color filter 2A. Further, the first color filter 2A is provided with the protective film 4 having the irregularity 401. Additionally, the second color filter 2B is provided with the protective film 4 having the irregularity 402 that is larger than the irregularity 401.

It is therefore possible for the irregularity 401 and the irregularity 402 of the protective film 4 to scatter reflected light for the incident light L in a manner to correspond to the transmitted wavelength of light of the color filter 2 and thus to reduce reflected light. This makes it possible, in the solid-state imaging device 1, to effectively suppress or prevent a flare phenomenon.

### 12. Twelfth Embodiment

Next, description is given of the solid-state imaging device 1 according to the twelfth embodiment of the present disclosure.

### [Configuration of Solid-State Imaging Device 1]

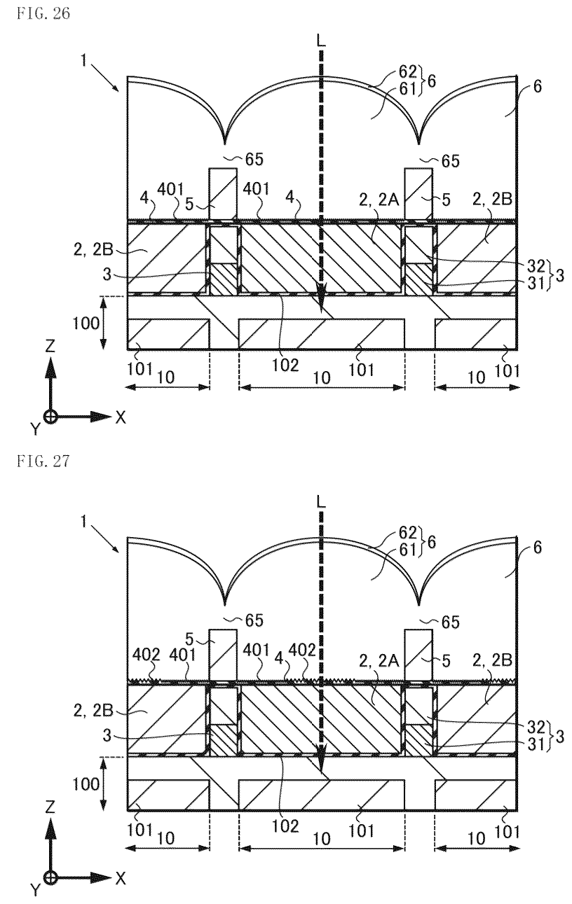

FIG. 25 illustrates an example of a longitudinal cross-sectional configuration of the plurality of pixels 10 arrayed in the middle portion of the pixel region PA in the solid-state imaging device 1. FIG. 26 illustrates an example of a longitudinal cross-sectional configuration of the plurality of pixels 10 arrayed in the peripheral portion of the pixel region PA in the solid-state imaging device 1.

As illustrated in FIGS. 25 and 26, in the solid-state imaging device 1 according to the twelfth embodiment, the structure of the protective film 4 of the solid-state imaging device 1 according to the tenth embodiment is changed.

To describe this in more detail, the pixel region PA (see FIG. 2) includes the middle portion and the peripheral portion. As illustrated in FIG. 25, in the middle portion of the pixel region PA, the color filter 2 is provided with the protective film 4 having the irregularity 402. Meanwhile, as illustrated in FIG. 26, in the peripheral portion of the pixel region PA, the color filter 2 is provided with the protective film 4 having the irregularity 401. Here, the irregularity 402 is larger than the irregularity 401.

Components other than those described above are the same or substantially the same as the components of the solid-state imaging device 1 according to the tenth embodiment.

### [Workings and Effects]

In the solid-state imaging device 1 according to the twelfth embodiment, it is possible to obtain workings and effects similar to the workings and effects obtained by the solid-state imaging device 1 according to the tenth embodiment.

In addition, in the solid-state imaging device 1 according to the twelfth embodiment, as illustrated in FIG. 25, the color filter 2 is provided with the protective film 4 having the irregularity 402, in the middle portion of the pixel region PA. Meanwhile, as illustrated in FIG. 26, the color filter 2 is provided with the protective film 4 having the irregularity 401, in the peripheral portion of the pixel region PA. The irregularity 402 is larger than the irregularity 401.

It is therefore possible for the irregularity 401 and the irregularity 402 of the protective film 4 to scatter reflected light for the incident light L in a manner to correspond to a light amount of the incident light L and thus to reduce reflected light. This makes it possible, in the solid-state imaging device 1, to effectively suppress or prevent a flare phenomenon.

It is to be noted that, in the solid-state imaging device 1 according to the twelfth embodiment, the irregular shape may be smaller continuously or gradually from the irregularity 402 to the irregularity 401 of the protective film 4 from the middle portion toward the peripheral portion of the pixel region PA. In other words, the cycle of the irregularity may be adjusted continuously or gradually.

### 13. Thirteenth Embodiment

Next, description is given of the solid-state imaging device 1 according to the thirteenth embodiment of the present disclosure.

### [Configuration of Solid-State Imaging Device 1]

FIG. 27 illustrates an example of a longitudinal cross-sectional configuration of the plurality of pixels 10 arrayed in the pixel region PA of the solid-state imaging device 1.

As illustrated in FIG. 27, in the solid-state imaging device 1 according to the thirteenth embodiment, the structure of the protective film 4 of the solid-state imaging device 1 according to the tenth embodiment is changed.

To describe this in more detail, the pixel 10 is provided with the color filter 2. In a middle part of the pixel 10, the protective film 4 has the irregularity 402. In a peripheral part of the pixel 10, the protective film 4 has the irregularity 401. Here, the irregularity 402 is larger than the irregularity 401.

Components other than those described above are the same or substantially the same as the components of the solid-state imaging device 1 according to the tenth embodiment.

### [Workings and Effects]

In the solid-state imaging device 1 according to the thirteenth embodiment, it is possible to obtain workings and effects similar to the workings and effects obtained by the solid-state imaging device 1 according to the tenth embodiment.

In addition, in the solid-state imaging device 1 according to the thirteenth embodiment, as illustrated in FIG. 27, the protective film 4 has the irregularity 402 in the middle part of the pixel 10, and the protective film 4 has the irregularity 401 in the peripheral part of the pixel 10. The irregularity 402 is larger than the irregularity 401.

It is therefore possible for the irregularity 401 and the irregularity 402 of the protective film 4 to scatter reflected light for the incident light L in a manner to correspond to the light amount of the incident light L and thus to reduce reflected light. This makes it possible, in the solid-state imaging device 1, to effectively suppress or prevent a flare phenomenon.

It is to be noted that, in the solid-state imaging device 1 according to the thirteenth embodiment, the irregular shape may be smaller continuously or gradually from the irregularity 402 to the irregularity 401 of the protective film 4 from the middle part toward the peripheral part of the pixel 10. In other words, the cycle of the irregularity may be adjusted continuously or gradually.

### 14. Fourteenth Embodiment

Next, description is given of the solid-state imaging device 1 according to the fourteenth embodiment of the present disclosure.

### [Configuration of Solid-State Imaging Device 1]

FIG. 28 illustrates an example of a longitudinal cross-sectional configuration of the plurality of pixels 10 arrayed in the pixel region PA of the solid-state imaging device 1.

As illustrated in FIG. 28, in the solid-state imaging device 1 according to the fourteenth embodiment, the structure of the inter-filter partition wall 3 of the solid-state imaging device 1 according to the first embodiment is changed.

To describe this in more detail, the inter-filter partition wall 3 includes the light-blocking film 31, and the low refractive index film 32 stacked on the light-blocking film 31. For the light-blocking film 31, for example, there may be practically used one or more materials selected from titanium nitride (TiN), titanium oxide (TiO₂), and aluminum oxide (Al₂O₃). For example, titanium (Ti) or the like may be practically used for the low refractive index film 32.

Here, the inter-filter partition wall 3 is formed to have a height (thickness) in the arrow-Z direction of 100 nm or more, for examples. In addition, the color filter 2 is formed by a spin-coating method, and thus the height of the inter-filter partition wall 3 is set to be equal to or less than the thickness of the color filter 2, in order to have favorable coatability.

In addition, the inter-filter partition wall 3 may be formed by a monolayer metal film. In this case, W, Al, or the like may be practically used for the metal film.

Components other than those described above are the same or substantially the same as the components of the solid-state imaging device 1 according to the tenth embodiment.

### [Workings and Effects]

In the solid-state imaging device 1 according to the fourteenth embodiment, it is possible to obtain workings and effects similar to the workings and effects obtained by the solid-state imaging device 1 according to the first embodiment.

### 15. Fifteenth Embodiment

Next, description is given of the solid-state imaging device 1 according to the fifteenth embodiment of the present disclosure.

### [Configuration of Solid-State Imaging Device 1]

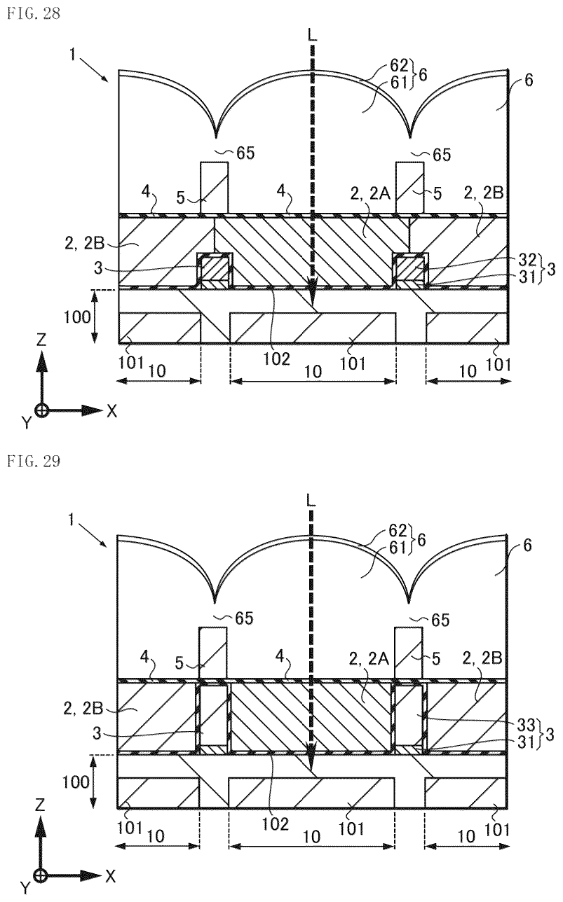

FIG. 29 illustrates an example of a longitudinal cross-sectional configuration of the plurality of pixels 10 arrayed in the pixel region PA of the solid-state imaging device 1.

As illustrated in FIG. 29, in the solid-state imaging device 1 according to the fifteenth embodiment, the structure of the inter-filter partition wall 3 of the solid-state imaging device 1 according to the first embodiment is changed.

To describe this in more detail, the inter-filter partition wall 3 includes the light-blocking film 31, and a low refractive index film 33 stacked on the light-blocking film 31. In the same manner as the light-blocking film 31 of the solid-state imaging device 1 according to the fourteenth embodiment, for example, one or more materials selected from TIN, TiO₂, and Al₂O₃ may be practically used for the light-blocking film 31. For the low refractive index film 33, for example, there may be practically used one or more low refractive index materials selected from SiO₂, SiOC, an organic resin, and an organic resin containing a filler. Here, the low refractive index refers to 1.6 or less, for example.

Components other than those described above are the same or substantially the same as the components of the solid-state imaging device 1 according to the fourteenth embodiment.

### [Workings and Effects]

In the solid-state imaging device 1 according to the fifteenth embodiment, it is possible to obtain workings and effects similar to the workings and effects obtained by the solid-state imaging device 1 according to the fourteenth embodiment.

### 16. Sixteenth Embodiment

Next, description is given of the solid-state imaging device 1 according to the sixteenth embodiment of the present disclosure.

### [Configuration of Solid-State Imaging Device 1]

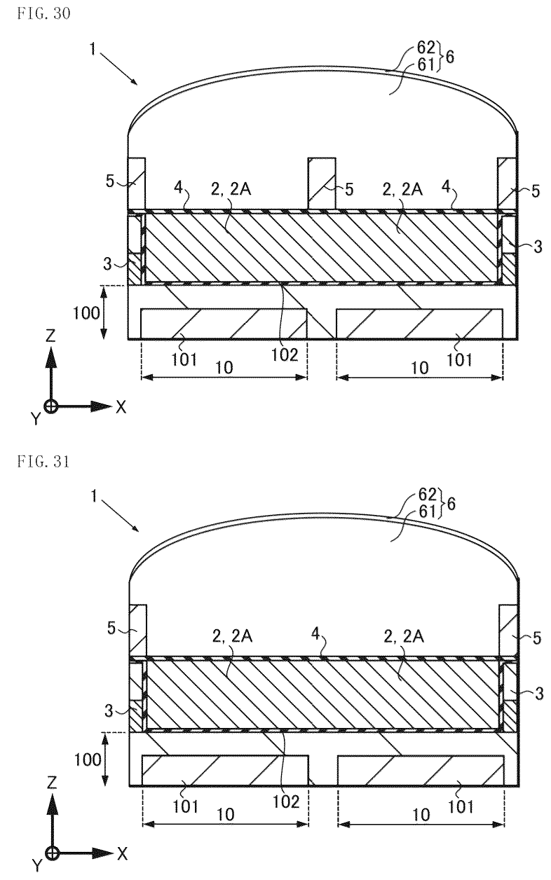

FIG. 30 illustrates an example of a longitudinal cross-sectional configuration of the plurality of pixels 10 arrayed in the pixel region PA of the solid-state imaging device 1.

As illustrated in FIG. 30, the solid-state imaging device 1 according to the sixteenth embodiment is an example in which a phase detection autofocus (PDAF: Phase Detection Auto Focus) technology is employed in the solid-state imaging device 1 according to the first embodiment.

To describe this in more detail, in the solid-state imaging device 1, one color filter 2 is disposed for two pixels 10 adjacent to each other in the arrow-X direction, and the optical lens 6 is disposed on the color filter 2. The optical lens 6 is formed to correspond to the two pixels 10 adjacent to each other in the arrow-X direction, and is formed to correspond to one pixel 10 in the arrow-Y direction. That is, the optical lens 6 has an aspect ratio of longer in the arrow-X direction and shorter in the arrow-Y direction.

Here, the inter-filter partition wall 3 is disposed at a position corresponding to every two adjacent pixels in the arrow-X direction, and the inter-lens partition wall 5 is disposed at a position corresponding to each of adjacent pixels 10 in the arrow-X direction.

In the same manner as the solid-state imaging device 1 according to the first embodiment, the protective film 4 is disposed on the color filter 2 between the color filter 2 and the inter-lens partition wall 5.

Components other than those described above are the same or substantially the same as the components of the solid-state imaging device 1 according to the first embodiment.

### [Workings and Effects]

In the solid-state imaging device 1 according to the sixteenth embodiment, it is possible to obtain workings and effects similar to the workings and effects obtained by the solid-state imaging device 1 according to the first embodiment.

In addition, the PDAF is employed in the solid-state imaging device 1, as illustrated in FIG. 30. This makes it possible to improve PDAF characteristics.

### Modification Example

Next, description is given of the solid-state imaging device 1 according to a modification example of the sixteenth example.

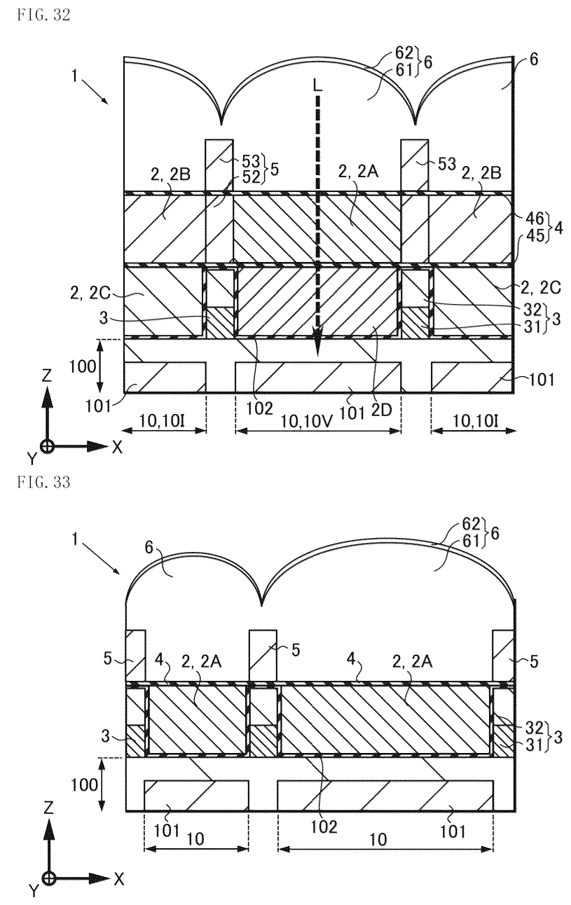

FIG. 31 illustrates an example of a longitudinal cross-sectional configuration of the plurality of pixels 10 arrayed in the pixel region PA of the solid-state imaging device 1.

In the solid-state imaging device 1 according to the modification example, as illustrated in FIG. 31, the inter-filter partition wall 3 is disposed at a position corresponding to every two adjacent pixels 10 in the arrow-X direction, and the inter-lens partition wall 5 is disposed at a position corresponding to every two adjacent pixels 10 in the arrow-X direction.

Components other than those described above are the same or substantially the same as the components of the solid-state imaging device 1 according to the sixteenth embodiment.

In the solid-state imaging device 1 according to the modification example, it is possible to obtain workings and effects similar to the workings and effects obtained by the solid-state imaging device 1 according to the sixteenth embodiment.

### 17. Seventeenth Embodiment

Next, description is given of the solid-state imaging device 1 according to the seventeenth embodiment of the present disclosure.

### [Configuration of Solid-State Imaging Device 1]

FIG. 32 illustrates an example of a longitudinal cross-sectional configuration of the plurality of pixels 10 arrayed in the pixel region PA of the solid-state imaging device 1.

As illustrated in FIG. 32, in the solid-state imaging device 1 according to the seventeenth embodiment, the structure of the color filter 2 of the solid-state imaging device 1 according to the first embodiment is changed.

To describe this in more detail, the solid-state imaging device 1 includes a pixel 10V that receives visible light and a pixel 10I that receives infrared light.

The pixel 10V includes a cut filter 2D, and the first color filter 2A stacked on the cut filter 2D. The first color filter 2A is a color filter having a green color. The cut filter 2D is an infrared light cut filter.

The pixel 10I includes the third color filter 2C, and the second color filter 2B stacked on the third color filter 2C. The third color filter 2C is a color filter having a blue color. The second color filter 2B is a color filter having a red color.

The inter-filter partition wall 3 is disposed between the cut filter 2D of the pixel 10V and the third color filter 2C of the pixel 10I at a corresponding position between the pixels 10 adjacent to each other.

Meanwhile, an inter-lens partition wall 52 is disposed between the first color filter 2A of the pixel 10V and the second color filter 2B of the pixel 10I at a corresponding position between the pixels 10 adjacent to each other. In addition, an inter-lens partition wall 53 is further disposed on the inter-lens partition wall 52 and around the side surface of the optical lens 6. That is, the inter-lens partition wall 5 is formed by a two-layer structure in the arrow-Z direction.

Additionally, a protective film 45 of the first layer is disposed on the cut filter 2D and the third color filter 2C, and a protective film 46 of the second layer is disposed on the first color filter 2A and the second color filter 2B. That is, the protective film 4 is formed by a two-layer structure.

Components other than those described above are the same or substantially the same as the components of the solid-state imaging device 1 according to the first embodiment.

### [Workings and Effects]

In the solid-state imaging device 1 according to the seventeenth embodiment, it is possible to obtain workings and effects similar to the workings and effects obtained by the solid-state imaging device 1 according to the first embodiment.

In addition, in the solid-state imaging device 1, as illustrated in FIG. 32, the protective film 45 of the first layer is disposed on the cut filter 2D and the third color filter 2C. This allows the protective film 45 to protect the cut filter 2D and the third color filter 2C, thus making it possible to effectively suppress or prevent damage to the color filter 2.

Additionally, in the solid-state imaging device 1, the protective film 46 of the second layer is disposed on the first color filter 2A and the second color filter 2B. This allows the protective film 46 to protect the first color filter 2A and the second color filter 2B, thus making it possible to effectively suppress or prevent damage to the color filter 2.

### 18. Eighteenth Embodiment

Next, description is given of the solid-state imaging device 1 according to the eighteenth embodiment of the present disclosure.

### [Configuration of Solid-State Imaging Device 1]

FIG. 33 illustrates an example of a longitudinal cross-sectional configuration of the plurality of pixels 10 arrayed in the pixel region PA of the solid-state imaging device 1.

As illustrated in FIG. 33, in the solid-state imaging device 1 according to the eighteenth embodiment, the structure of the pixel 10 of the solid-state imaging device 1 according to the first embodiment is changed.

To describe this in more detail, here, sizes of two pixels 10 adjacent to each other in the arrow-X direction are different in the adjacent direction. As compared with one pixel 10, another pixel 10 adjacent thereto in the arrow-X direction is formed to be larger in size.

Components other than those described above are the same or substantially the same as the components of the solid-state imaging device 1 according to the first embodiment.

### [Workings and Effects]

In the solid-state imaging device 1 according to the eighteenth embodiment, it is possible to obtain workings and effects similar to the workings and effects obtained by the solid-state imaging device 1 according to the first embodiment.

### 19. Nineteenth Embodiment

Next, description is given of the solid-state imaging device 1 according to the nineteenth embodiment of the present disclosure.

### [Configuration of Solid-State Imaging Device 1]

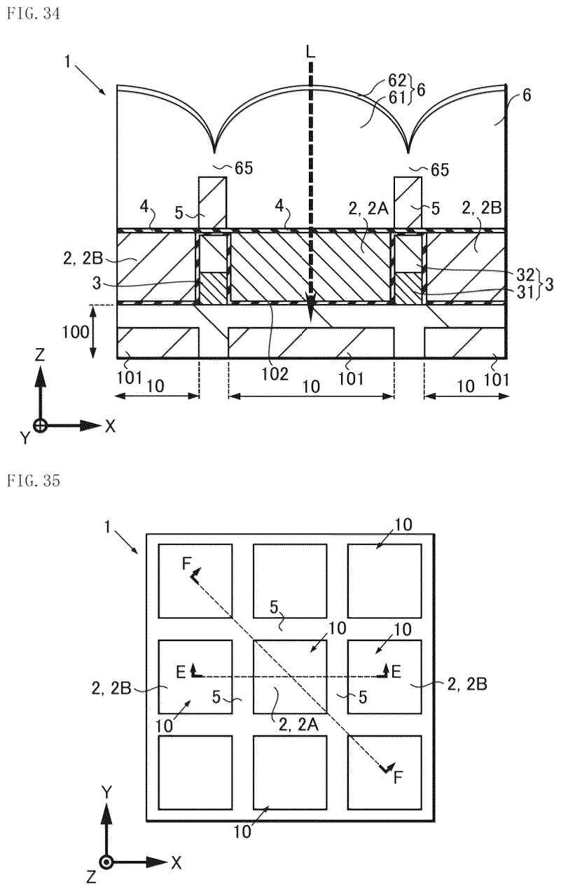

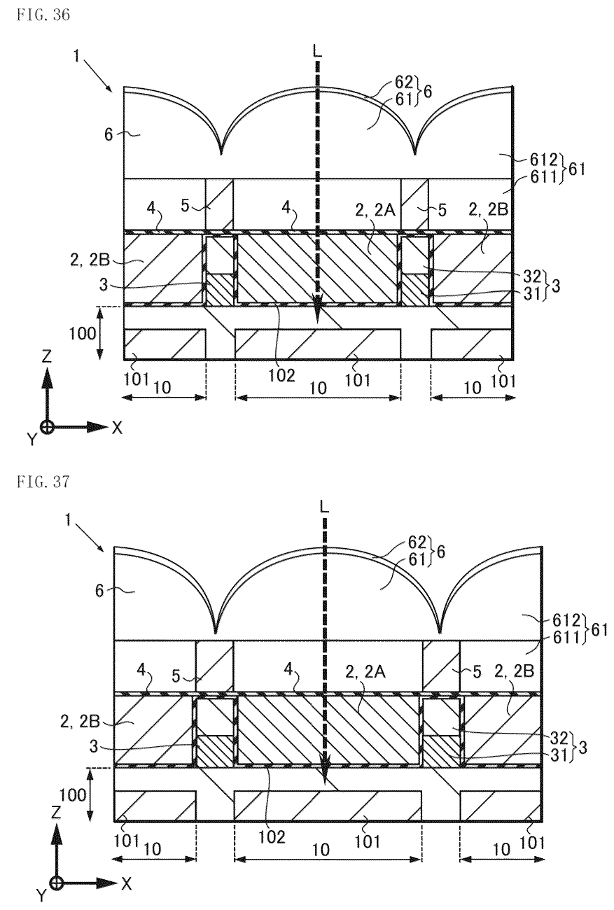

FIG. 34 illustrates an example of a longitudinal cross-sectional configuration of the plurality of pixels 10 arrayed in the pixel region PA of the solid-state imaging device 1.

As illustrated in FIG. 34, in the solid-state imaging device 1 according to the nineteenth embodiment, the structure of the optical lens 6 of the solid-state imaging device 1 according to the first embodiment is changed.

To describe this in more detail, in the optical lens 6, a high refractive index material is used to form the lens main body 61. The lens main body 61 has a refractive index of 1.65 or more and 2.0 or less. For the lens main body 61, for example, there may be practically used one or more materials selected from a metal oxide, an organic resin containing an oxide filler, SiO₂, and SiN.

Components other than those described above are the same or substantially the same as the components of the solid-state imaging device 1 according to the first embodiment.

### [Workings and Effects]

In the solid-state imaging device 1 according to the nineteenth embodiment, it is possible to obtain workings and effects similar to the workings and effects obtained by the solid-state imaging device 1 according to the first embodiment.

### 20. Twentieth Embodiment

Next, description is given of the solid-state imaging device 1 according to the twentieth embodiment of the present disclosure.

### [Configuration of Solid-State Imaging Device 1]

FIG. 35 illustrates an example of a planar configuration of the plurality of pixels 10 arrayed in the pixel region PA of the solid-state imaging device 1. FIG. 36 illustrates an example of a longitudinal cross-sectional configuration of the pixels 10 taken along a section line E-E illustrated in FIG. 35. FIG. 37 illustrates an example of a longitudinal cross-sectional configuration of the pixels 10 taken along a section line F-F illustrated in FIG. 35.

As illustrated in FIGS. 35 to 37, in the solid-state imaging device 1 according to the twentieth embodiment, the structures of the optical lens 6 and the inter-lens partition wall 5 of the solid-state imaging device 1 according to the first embodiment are changed.

To describe this in more detail, in the solid-state imaging device 1, the lens main body 61 of the optical lens 6 includes a first lens main body 611 and a second lens main body 612. The second lens main body 612 is stacked on the first lens main body 611 on a side opposite to the color filter 2, and is integrally formed with the first lens main body 611.

Here, the magnitudes of respective refractive indexes of the protective film 4, the first lens main body 611, and the second lens main body 612 are in a relationship of the following expression.

Protective Film 4>First Lens Main Body 611>Second Lens Main Body 612

It is to be noted that, the refractive index of the first lens main body 611 and the refractive index of the second lens main body 612 may be the same as or different from each other, as indicated by the above expression. In a case where the refractive indexes differ from each other, the refractive index of the first lens main body 611 is larger than the refractive index of the second lens main body 612.

In addition, the inter-lens partition wall 5 is disposed between the first lens main bodies 611 adjacent to each other. The thickness (height) of the inter-lens partition wall 5 in the arrow-Z direction is substantially coincident with a thickness of the first lens main body 611 in the same direction.

### [Manufacturing Method of Solid-State Imaging Device 1]

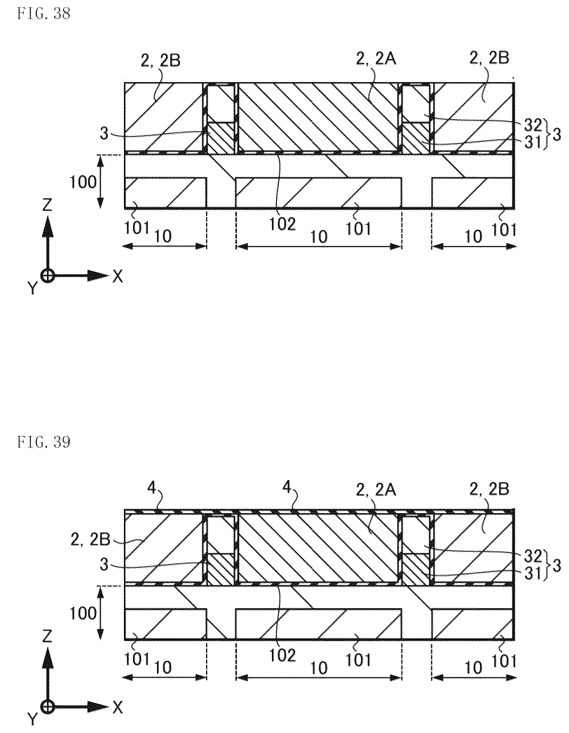

FIGS. 38 to 46 are each an explanatory step cross-sectional view of the manufacturing method of the solid-state imaging device 1 according to the twentieth embodiment. The manufacturing method of the solid-state imaging device 1 is as follows.

First, the photoelectric conversion element 101 is formed in the substrate 100, and the pixel 10 is formed (see FIGS. 36 and 37). Thereafter, in the same manner as the step illustrated in FIG. 3 of the first manufacturing method, the color filter 2 is formed at a position corresponding to the pixel 10, and the inter-filter partition wall 3 is formed at a corresponding position between the pixels 10, as illustrated in FIG. 38.

In the same manner as the step illustrated in FIG. 4 of the first manufacturing method, the protective film 4 is formed across the entire surface on the color filter 2 and the inter-filter partition wall 3, as illustrated in FIG. 39.

When a resin material is used for the protective film 4, the protective film 4 is formed by a spin-coating method, for example. In addition, when an inorganic material is used for the protective film 4, the protective film 4 is formed by a spin-coating method, a CVD method, or a sputtering method, for example.

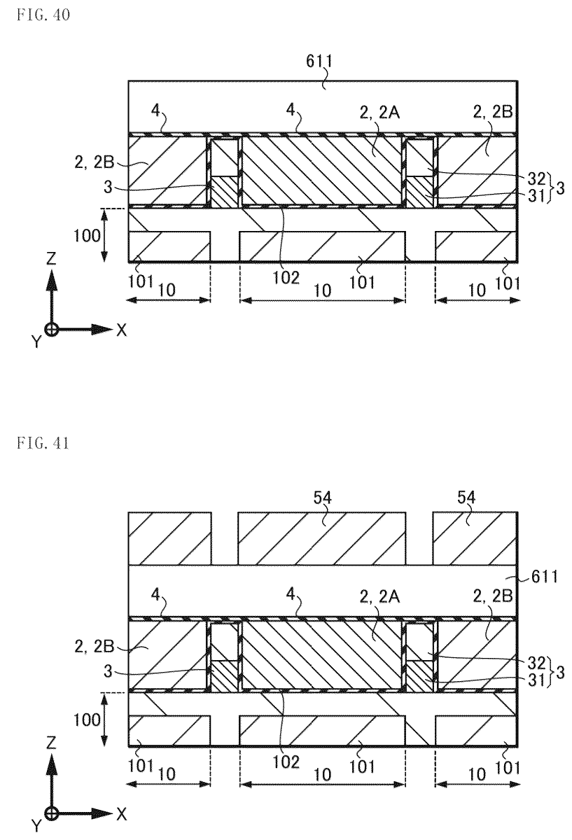

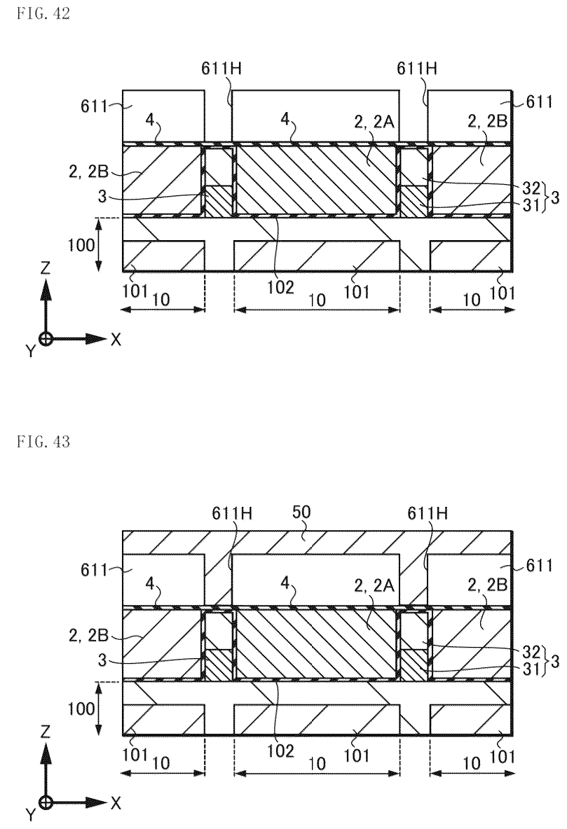

As illustrated in FIG. 40, the first lens main body 611 of the optical lens 6 is formed across the entire surface on the protective film 4. For example, a resin material is used for the first lens main body 611. The first lens main body 611 is formed by a spin-coating method, for example.

As illustrated in FIG. 41, a mask 54 is formed on the first lens main body 611. The mask 54 has an opening at a corresponding position between the pixels 10. The mask 54 is formed by a photolithography technique, for example.

The mask 54 is used to pattern the first lens main body 611. For example, dry etching is used for the patterning. The patterning allows for formation of an opening 611H in the first lens main body 611; the opening 611H is adapted to form the inter-lens partition wall 5.

Upon the formation of the opening 611H, the protective film 4 is used as an etching stopper film in the same manner as the protective film 4 in the first manufacturing method. Therefore, the color filter 2 exposed to the inside of the opening 611H is protected, thus making it possible to effectively suppress or prevent damage to the color filter 2 caused by the construction of the inter-lens partition wall 5.

In particular, in the solid-state imaging device 1 according to the seventh embodiment described above, the inter-lens partition wall 5 is disposed on the color filter 2, and thus the color filter 2 is effectively protected (see FIG. 20).

After the formation of the opening 611H, the mask 54 is removed, as illustrated in FIG. 42.

In the same manner as the step illustrated in FIG. 5 of the first manufacturing method, the partition wall formation layer 50 is formed across the entire surface on the first lens main body 611, as illustrated in FIG. 43. The partition wall formation layer 50 is also filled in the opening 611H between the first lens main bodies 611. For example, a resin material is used for the partition wall formation layer 50. The partition wall formation layer 50 is formed by a spin-coating method, for example.

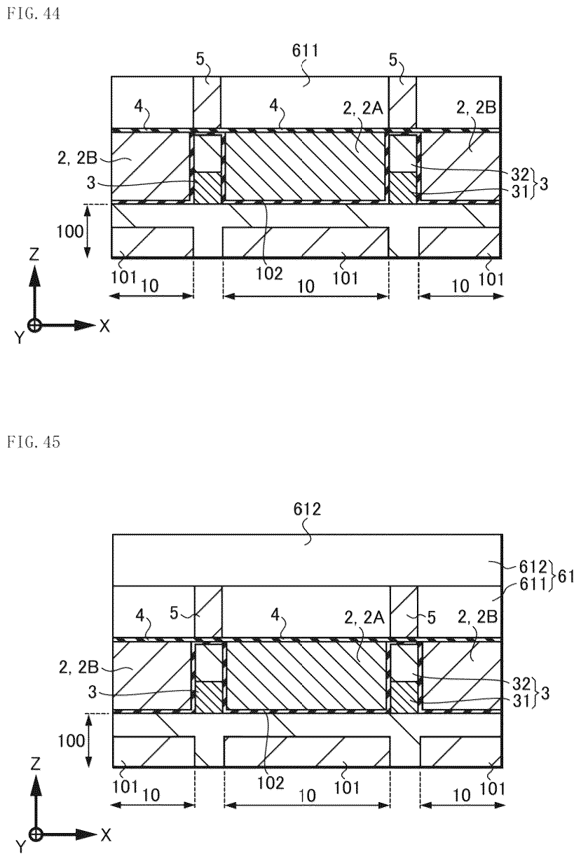

As illustrated in FIG. 44, the partition wall formation layer 50 on the first lens main body 611 is removed. Meanwhile, at the same time, the inter-lens partition wall 5 is formed by the partition wall formation layer 50 filled in the opening 611H. Dry etching or a chemical mechanical polishing (CMP: Chemical Mechanical Polishing) method is used to remove the partition wall formation layer 50.

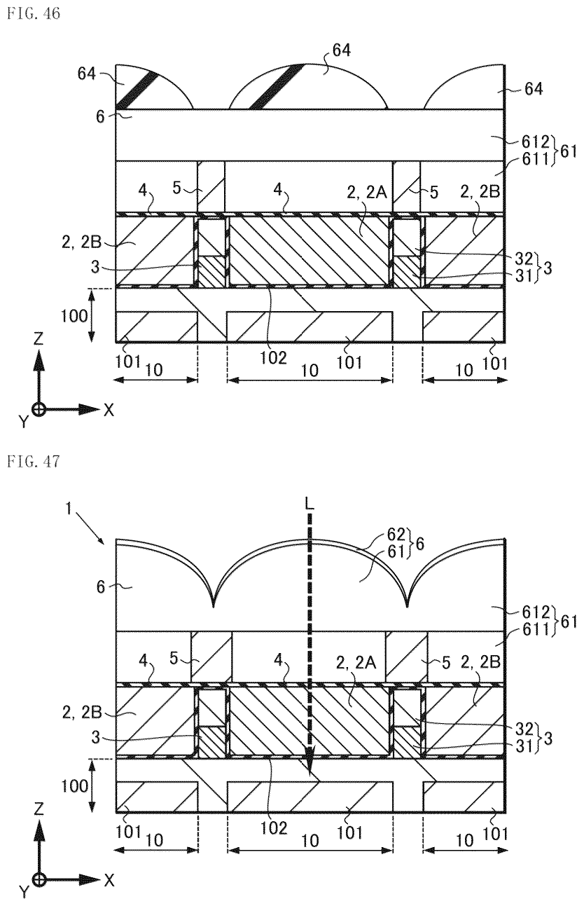

As illustrated in FIG. 45, the second lens main body 612 is formed on the first lens main body 611 and the inter-lens partition wall 5. The second lens main body 612 is formed using a resin material by a spin-coating method, for example.

As illustrated in FIG. 46, the mask 64 is formed on the second lens main body 612. The mask 64 is formed into a lens shape, for example, by forming a photoresist film, then performing patterning remaining at a position corresponding to the pixel 10, and thereafter performing reflow processing.

The mask 64 is used to pattern the second lens main body 612, and the second lens main body 612 is formed into a predetermined lens shape. For example, an etch-back method is used for the patterning.

Here, in the manufacturing method of the solid-state imaging device 1 according to the twentieth embodiment, the mask 64 is used to form the second lens main body 612. In the present technology, the second lens main body 612 may be patterned without using the mask 64 described above, and then reflow processing is performed to form the second lens main body 612 into a lens shape.

After the formation of the second lens main body 612, the antireflection film 62 is formed on the second lens main body 612, as illustrated in FIGS. 36 and 37 mentioned above. When the series of manufacturing steps ends, the solid-state imaging device 1 according to the twentieth embodiment is completed.

### [Workings and Effects]

In the solid-state imaging device 1 according to the twentieth embodiment, it is possible to obtain workings and effects similar to the workings and effects obtained by the solid-state imaging device 1 according to the first embodiment.

In addition, in the solid-state imaging device 1 according to the twentieth embodiment, as illustrated in FIGS. 36 and 37, the optical lens 6 includes the first lens main body 611 and the second lens main body 612. That is, it is possible to appropriately adjust the refractive index in the optical lens 6 in the path of the incident light L. For example, it is possible, in the optical lens 6, to gradually increase the refractive index toward the color filter 2.

This makes it possible to reduce the transmission loss of the incident light L while allowing the protective film 4 to effectively suppress or prevent damage to the color filter 2.

### 21. Twenty-First Embodiment

Next, description is given of the solid-state imaging device 1 according to the twenty-first embodiment of the present disclosure.

### [Configuration of Solid-State Imaging Device 1]

FIG. 47 illustrates an example of a longitudinal cross-sectional configuration of the plurality of pixels 10 arrayed in the pixel region PA of the solid-state imaging device 1.

As illustrated in FIG. 47, in the solid-state imaging device 1 according to the twenty-first embodiment, the structure of the inter-lens partition wall 5 of the solid-state imaging device 1 according to the twentieth embodiment is changed.

To describe this in more detail, the inter-lens partition wall 5 is formed to allow the width dimensions thereof in the arrow-X direction and the unillustrated arrow-Y direction to be larger than the width dimensions of the inter-filter partition wall 3 in the same directions.

Components other than those described above are the same or substantially the same as the components of the solid-state imaging device 1 according to the twentieth embodiment.

### [Workings and Effects]

In the solid-state imaging device 1 according to the twenty-first embodiment, it is possible to obtain workings and effects similar to the workings and effects obtained by the solid-state imaging device 1 according to the twentieth embodiment.

In addition, in the solid-state imaging device 1 according to the twenty-first embodiment, as illustrated in FIG. 47, it is possible to increase the width dimension of the inter-lens partition wall 5, thus making it possible to improve flexibility in design.

### 22. Twenty-Second Embodiment

Next, description is given of the solid-state imaging device 1 according to the twenty-second embodiment of the present disclosure.

### [Configuration of Solid-State Imaging Device 1]

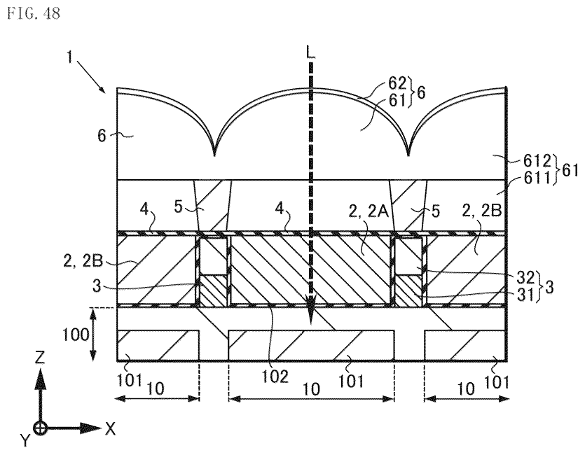

FIG. 48 illustrates an example of a longitudinal cross-sectional configuration of the plurality of pixels 10 arrayed in the pixel region PA of the solid-state imaging device 1.

As illustrated in FIG. 48, in the solid-state imaging device 1 according to the twenty-second embodiment, the structure of the inter-lens partition wall 5 of the solid-state imaging device 1 according to the twentieth embodiment is changed.

To describe this in more detail, the inter-lens partition wall 5 is formed to allow the width dimensions of the upper part thereof in the arrow-X direction and the unillustrated arrow-Y direction to be larger than the width dimensions of the lower part of the inter-lens partition wall 5 in the same directions. That is, in a side view, the inter-lens partition wall 5 is formed into an inverted trapezoidal shape.

Components other than those described above are the same or substantially the same as the components of the solid-state imaging device 1 according to the twentieth embodiment.

### [Workings and Effects]

In the solid-state imaging device 1 according to the twenty-second embodiment, it is possible to obtain workings and effects similar to the workings and effects obtained by the solid-state imaging device 1 according to the twentieth embodiment.

In addition, in the solid-state imaging device 1 according to the twenty-second embodiment, as illustrated in FIG. 48, it is possible to form the shape of the inter-lens partition wall 5 into an inverted trapezoidal shape, thus making it possible to improve flexibility in design.

### 23. Twenty-Third Embodiment

Next, description is given of the solid-state imaging device 1 according to the twenty-third embodiment of the present disclosure. The solid-state imaging device 1 according to any of the twenty-third to twenty-seventh embodiments is an example in which a phase difference detection pixel 10Pdd is arranged in at least a portion of the pixel region PA.

### [Configuration of Solid-State Imaging Device 1]

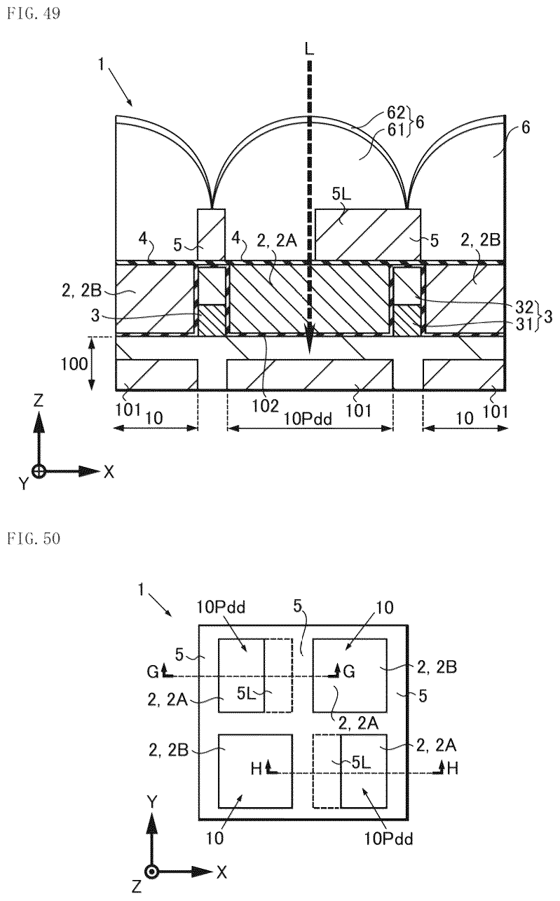

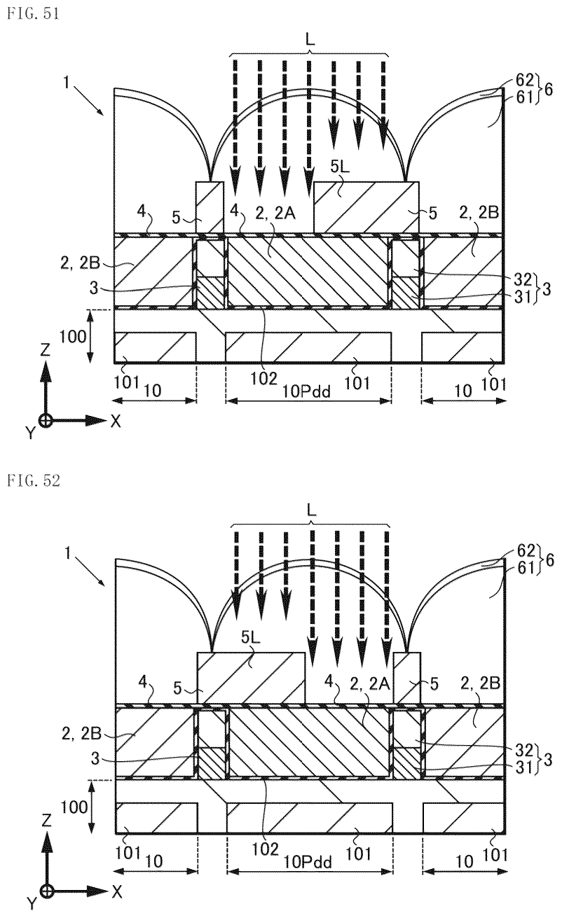

FIG. 49 illustrates an example of a longitudinal cross-sectional configuration of the plurality of pixels 10 and a plurality of phase difference detection pixels 10Pdd arrayed in the pixel region PA of the solid-state imaging device 1. FIG. 50 illustrates an example of a planar configuration of the pixels 10 and the phase difference detection pixels 10Pdd illustrated in FIG. 49.

As illustrated in FIGS. 49 and 50, in the solid-state imaging device 1 according to the twenty-third embodiment, at least some of the pixels 10 arrayed in the pixel region PA in the solid-state imaging device 1 according to the first embodiment are configured as the phase difference detection pixels 10Pdd.

To describe this in more detail, in the phase difference detection pixel 10Pdd, among the inter-lens partition walls 5 disposed along the peripheral part of the pixel 10, the inter-lens partition walls 5 having different width dimensions (widths) are disposed at positions opposed to each other. Here, one inter-lens partition wall 5 (on the right side in the drawing) disposed at an opposed position in the arrow-X direction is formed to have a width dimension larger than that of another inter-lens partition wall 5 (on the left side in the drawing).

The other inter-lens partition wall 5 includes an extended part 5L extended to a side of a middle part of the phase difference detection pixel 10Pdd from between the pixel 10 and the phase difference detection pixel 10Pdd, and is formed to overhang the phase difference detection pixel 10Pdd. In other words, the phase difference detection pixel 10Pdd is formed by utilizing the inter-lens partition wall 5 and changing the shape of the inter-lens partition wall 5.

FIG. 51 illustrates an example of an explanatory longitudinal cross-sectional configuration of a phase difference detection image in the phase difference detection pixel 10Pdd taken along a section line G-G illustrated in FIG. 50. FIG. 52 illustrates an example of an explanatory longitudinal cross-sectional configuration of a phase difference detection image in the phase difference detection pixel 10Pdd taken along a section line H-H illustrated in FIG. 50.

In the phase difference detection pixel 10Pdd illustrated in FIG. 51, the width dimension of the inter-lens partition wall 5 in the arrow-X direction is extended. Therefore, in the phase difference detection pixel 10Pdd, the incident light L enters an opening, of which a periphery is surrounded by the inter-lens partition wall 5, on the opposite side in the arrow-X direction.

Meanwhile, in the phase difference detection pixel 10Pdd illustrated in FIG. 52, the width dimension of the inter-lens partition wall 5 on the opposite side in the arrow-X direction is extended. Therefore, in the phase difference detection pixel 10Pdd, the incident light L enters an opening, of which a periphery is surrounded by the inter-lens partition wall 5, in the arrow-X direction.

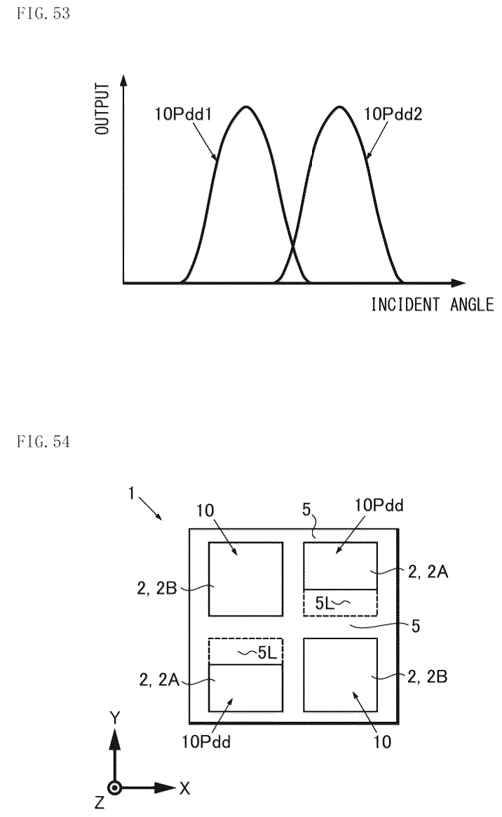

FIG. 53 illustrates an example of a relationship between an incident angle and an output at the time of detection of a phase difference of the phase difference detection pixel 10Pdd illustrated in FIGS. 51 and 52. The horizontal axis indicates an incident angle of the incident light L. The vertical axis indicates an output of the phase difference detection pixel 10Pdd. Here, the output characteristic of the phase difference detection pixel 10Pdd illustrated in FIG. 51 is indicated by a reference numeral “10Pdd1”, whereas the output characteristic of the phase difference detection pixel 10Pdd illustrated in FIG. 52 is indicated by a reference numeral “10Pdd2”.

In FIG. 53, as indicated by the reference numeral 10Pdd1, the phase difference detection pixel 10Pdd illustrated in FIG. 51 receives the incident light L passing through the inside of the opening formed on the opposite side in the arrow-X direction. Therefore, the output of the phase difference detection pixel 10Pdd generates a peak on the left side of the incident angle.

Meanwhile, as indicated by the reference numeral 10Pdd2, the phase difference detection pixel 10Pdd illustrated in FIG. 52 receives the incident light L passing through the opening formed on the side in the arrow-X direction. Therefore, the output of the phase difference detection pixel 10Pdd generates a peak on the right side of the incident angle.

Components other than those described above are the same or substantially the same as the components of the solid-state imaging device 1 according to the first embodiment.

### [Workings and Effects]

In the solid-state imaging device 1 according to the twenty-third embodiment, it is possible to obtain workings and effects similar to the workings and effects obtained by the solid-state imaging device 1 according to the first embodiment.

In addition, in the solid-state imaging device 1, as illustrated in FIGS. 49 and 50, the phase difference detection pixel 10Pdd is formed by utilizing the inter-lens partition walls 5 having different width dimensions. As illustrated in FIGS. 51 to 53, it is possible, in the phase difference detection pixel 10Pdd, to detect a phase difference from a difference in the output with respect to a change in the incident angle of the incident light L. Here, there are provided a pair of phase difference detection pixels 10Pdd having different incident angles in the arrow-X direction, thus enabling detection of a phase difference.

This makes it possible, in the solid-state imaging device 1, to achieve an autofocus function by utilizing the detected phase difference.

### 24. Twenty-Fourth Embodiment

Next, description is given of the solid-state imaging device 1 according to the twenty-fourth embodiment of the present disclosure. The solid-state imaging device 1 according to the twenty-fourth embodiment is an example in which the structure of the inter-lens partition wall 5 of the phase difference detection pixel 10Pdd is replaced in the solid-state imaging device 1 according to the twenty-third embodiment.

### [Configuration of Solid-State Imaging Device 1]

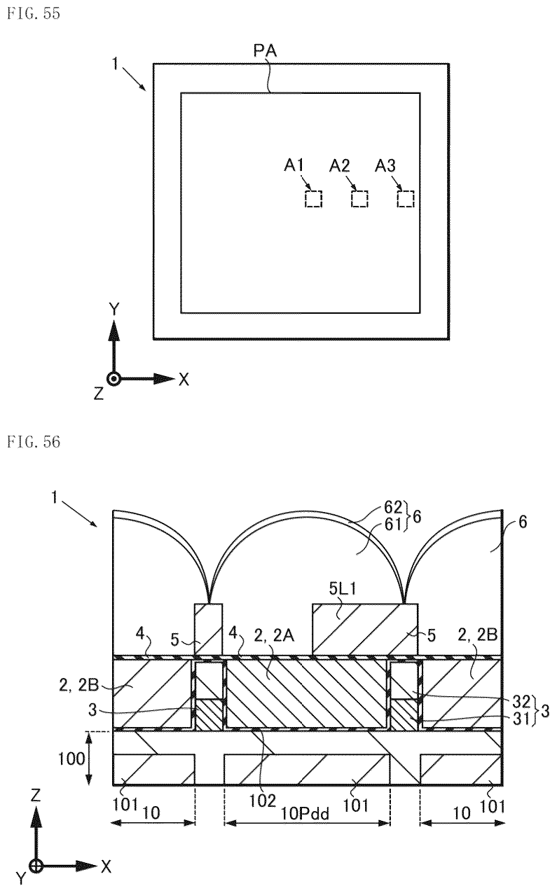

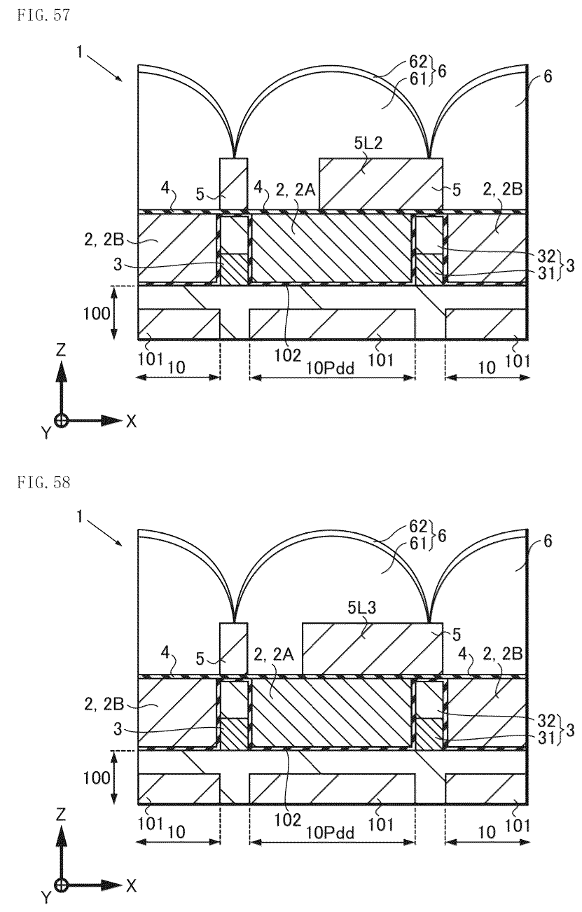

FIG. 54 illustrates an example of a planar configuration of the plurality of pixels 10 and the plurality of phase difference detection pixels 10Pdd arrayed in the pixel region PA of the solid-state imaging device 1.

In the phase difference detection pixel 10Pdd illustrated in FIG. 54, among the inter-lens partition walls 5 disposed along the peripheral part of the pixel 10, the inter-lens partition walls 5 having different width dimensions (widths) are disposed at positions opposed to each other. Here, one inter-lens partition wall 5 disposed at an opposed position in the arrow-Y direction is formed to have a width dimension larger than that of another inter-lens partition wall 5.

Components other than those described above are the same or substantially the same as the components of the solid-state imaging device 1 according to the twenty-third embodiment.

### [Workings and Effects]

In the solid-state imaging device 1 according to the twenty-fourth embodiment, it is possible to obtain workings and effects similar to the workings and effects obtained by the solid-state imaging device 1 according to the first embodiment.

In addition, in the solid-state imaging device 1, as illustrated in FIG. 54, the phase difference detection pixel 10Pdd is formed by utilizing the inter-lens partition walls 5 having different width dimensions. As illustrated in FIGS. 51 to 53 mentioned above, it is possible, in the phase difference detection pixel 10Pdd, to detect a phase difference from a difference in the output with respect to a change in the incident angle of the incident light L. Here, there are provided a pair of phase difference detection pixels 10Pdd having different incident angles in the arrow-Y direction, thus enabling detection of a phase difference.

This makes it possible, in the solid-state imaging device 1, to achieve an autofocus function by utilizing the detected phase difference.

It is to be noted that the solid-state imaging device 1 according to the twenty-fourth embodiment may be combined with the solid-state imaging device 1 according to the twenty-third embodiment. That is, it is possible to construct the solid-state imaging device 1 that includes a pair of phase difference detection pixels 10Pdd having different incident angles in each of the arrow-X direction and the arrow-Y direction and that detects a phase difference.

### 25. Twenty-Fifth Embodiment

Next, description is given of the solid-state imaging device 1 according to the twenty-fifth embodiment of the present disclosure. The solid-state imaging device 1 according to the twenty-fifth embodiment is an example in which the structure of the inter-lens partition wall 5 of the phase difference detection pixel 10Pdd arranged at a plurality of locations in the pixel region PA is replaced in the solid-state imaging device 1 according to the twenty-third embodiment.

### [Configuration of Solid-State Imaging Device 1]

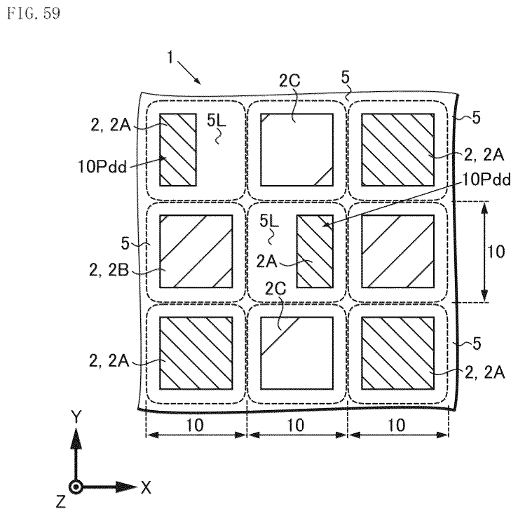

FIG. 55 illustrates an example of a planar configuration of the plurality of pixels 10 and the plurality of phase difference detection pixels 10Pdd arrayed in the pixel region PA of the solid-state imaging device 1. FIG. 56 illustrates an example of a longitudinal cross-sectional configuration of the phase difference detection pixel 10Pdd disposed in a region A1 in the middle portion of the pixel region PA illustrated in FIG. 55. FIG. 57 illustrates an example of a longitudinal cross-sectional configuration of the phase difference detection pixel 10Pdd disposed in a region A2 between the middle portion and the peripheral portion of the pixel region PA. FIG. 58 illustrates an example of a longitudinal cross-sectional configuration of the phase difference detection pixel 10Pdd disposed in a region A3 in the peripheral portion of the pixel region PA.

As illustrated in FIG. 55, in the solid-state imaging device 1 according to the twenty-fifth embodiment, the phase difference detection pixels 10Pdd are disposed at the plurality of locations of the pixel region PA. Here, the phase difference detection pixels 10Pdd are disposed at a total of three locations: the region A1 in the middle portion of the pixel region PA; the region A2 between the middle portion and the peripheral portion of the pixel region PA; and the region A3 in the peripheral portion of the pixel region PA.

As illustrated in FIG. 56, in the phase difference detection pixel 10Pdd disposed in the region A1, the inter-lens partition wall 5 includes an extended part 5L1 extended from between the pixel 10 and the phase difference detection pixel 10Pdd to the side of the middle part of the phase difference detection pixel 10Pdd. As illustrated in FIG. 57, in the phase difference detection pixel 10Pdd disposed in the region A2, the inter-lens partition wall 5 includes an extended part 5L2 extended from between the pixel 10 and the phase difference detection pixel 10Pdd to the side of the middle part of the phase difference detection pixel 10Pdd. The amount of overhanging of the extended part 5L2 is larger than the amount of overhanging of the extended part 5L1.

As illustrated in FIG. 58, in the phase difference detection pixel 10Pdd disposed in the region A3, the inter-lens partition wall 5 includes an extended part 5L3 extended from between the pixel 10 and the phase difference detection pixel 10Pdd to the side of the middle part of the phase difference detection pixel 10Pdd. The amount of overhanging of the extended part 5L3 is larger than the amount of overhanging of the extended part 5L2.

That is, in the pixel region PA, the phase difference detection pixels 10Pdd are arrayed, in which the width dimension of the inter-lens partition wall 5 is increased continuously (or gradually) from the region A1 in the middle portion toward the region A3 in the peripheral portion, depending on an amount of pupil correction.

It is to be noted that the number of locations in the array of the phase difference detection pixels 10Pdd may be two or four or more. Further, the phase difference detection pixels 10Pdd may be arrayed, in which the width dimension of the inter-lens partition wall 5 is decreased continuously (or gradually) from the region A1 toward the region A3 of the pixel region PA.

Components other than those described above are the same or substantially the same as the components of the solid-state imaging device 1 according to the twenty-third embodiment.

### [Workings and Effects]

In the solid-state imaging device 1 according to the twenty-fifth embodiment, it is possible to obtain workings and effects similar to the workings and effects obtained by the solid-state imaging device 1 according to the twenty-third embodiment.

In addition, in the solid-state imaging device 1, as illustrated in FIGS. 55 to 58, the width dimensions of the inter-lens partition walls 5 of the plurality of arrayed phase difference detection pixels 10Pdd are varied from the middle portion toward the peripheral portion of the pixel region PA, thus making it possible to detect a phase difference depending on the amount of pupil correction.

### 26. Twenty-Sixth Embodiment

Next, description is given of the solid-state imaging device 1 according to the twenty-sixth embodiment of the present disclosure. The solid-state imaging device 1 according to any of the twenty-sixth and twenty-seventh embodiments is employed for description of a relationship between the phase difference detection pixel 10Pdd and the color filter 2.

### [Configuration of Solid-State Imaging Device 1]

FIG. 59 illustrates an example of a planar configuration of the plurality of pixels 10 and the plurality of phase difference detection pixels 10Pdd arrayed in the pixel region PA of the solid-state imaging device 1.

As illustrated in FIG. 59, in the solid-state imaging device 1 according to the twenty-sixth embodiment, the pixels 10 are arrayed in a “1×1 pixel array” in the pixel region PA. To describe this in more detail, first, in the first line in the arrow-Y direction, the pixel 10 in which the color filter 2A is arranged and the pixel 10 in which the color filter 2C is arranged are each alternately arrayed in the arrow-X direction. In the second line in the arrow-Y direction, the pixel 10 in which the color filter 2B is arranged and the pixel 10 in which the color filter 2A is arranged are each alternately arrayed in the arrow-X direction. Further, in the third line in the arrow-Y direction, the pixel 10 in which the color filter 2A is arranged and the pixel 10 in which the color filter 2C is arranged are each alternately arrayed in the arrow-X direction, in the same manner as the first line.

Here, the phase difference detection pixel 10Pdd is disposed instead of the pixel 10 in which the color filter 2A is arranged in each of the second line in the arrow-Y direction and the third line in the arrow-Y direction. In the same manner as the solid-state imaging device 1 according to the twenty-third embodiment, in the phase difference detection pixel 10Pdd, the width dimensions of the opposed inter-lens partition walls 5 in the arrow-X direction are varied.

Components other than those described above are the same or substantially the same as the components of the solid-state imaging device 1 according to the twenty-third embodiment.

### [Workings and Effects]

In the solid-state imaging device 1 according to the twenty-sixth embodiment, it is possible to obtain workings and effects similar to the workings and effects obtained by the solid-state imaging device 1 according to the twenty-third embodiment.

In addition, in the solid-state imaging device 1, as illustrated in FIG. 59, it is possible to dispose the phase difference detection pixel 10Pdd without a constraint on the array of the color filters 2.

### 27. Twenty-Seventh Embodiment

Next, description is given of the solid-state imaging device 1 according to the twenty-seventh embodiment of the present disclosure.

### [Configuration of Solid-State Imaging Device 1]

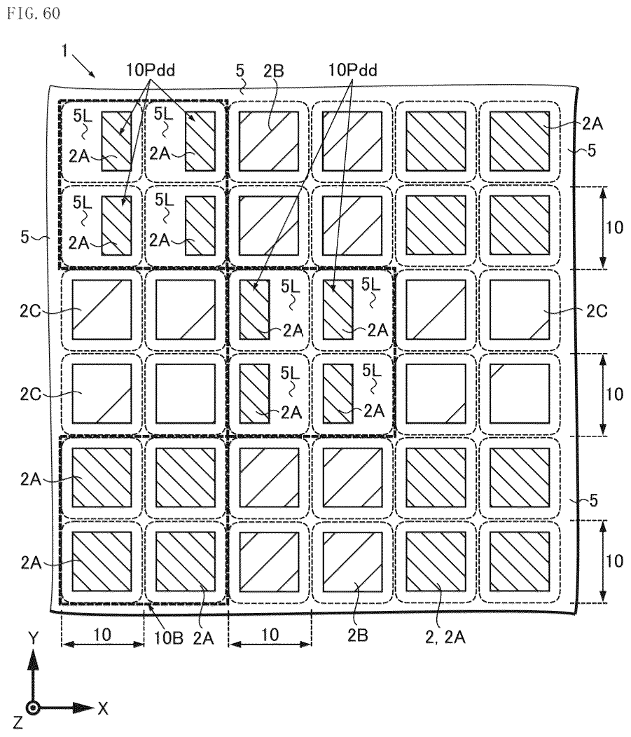

FIG. 60 illustrates an example of a planar configuration of the plurality of pixels 10 and the plurality of phase difference detection pixels 10Pdd arrayed in the pixel region PA of the solid-state imaging device 1.

As illustrated in FIG. 60, in the solid-state imaging device 1 according to the twenty-seventh embodiment, the pixels 10 are arrayed in a “2×2 pixel array” in the pixel region PA. To describe this in more detail, first, a total of four pixels 10, i.e., two pixels 10 arrayed in the arrow-X direction and two pixels 10 arrayed in the arrow-Y direction are set as a “unit pixel 10B”, in which the color filters 2 of the same color are arranged. In the pixel region PA, the unit pixels 10B are arrayed in the arrow-X direction and the arrow-Y direction.

In the first line in the arrow-Y direction, the unit pixel 10B in which the color filters 2A are arranged and the unit pixel 10B in which the color filters 2B are arranged are each alternately arrayed in the arrow-X direction. In the second line in the arrow-Y direction, the unit pixel 10B in which the color filters 2C are arranged and the unit pixel 10B in which the color filters 2A are arranged are each alternately arrayed in the arrow-X direction. Further, in the third line in the arrow-Y direction, the unit pixel 10B in which the color filters 2A are arranged and the unit pixel 10B in which the color filters 2B are arranged are each alternately arrayed in the arrow-X direction, in the same manner as the first line.

Here, in each of the second line in the arrow-Y direction and the third line in the arrow-Y direction, the phase difference detection pixel 10Pdd is disposed instead of the unit pixel 10B in which the color filters 2A are arranged.

Components other than those described above are the same or substantially the same as the components of the solid-state imaging device 1 according to the twenty-sixth embodiment.

### [Workings and Effects]

In the solid-state imaging device 1 according to the twenty-seventh embodiment, it is possible to obtain workings and effects similar to the workings and effects obtained by the solid-state imaging device 1 according to the twenty-sixth embodiment.

### 28. Example of Practical Application to Mobile Body

A technique according to the present disclosure (the present technology) is applicable to various products. For example, the technique according to the present disclosure may be achieved as an apparatus to be mounted on any type of mobile body such as an automobile, an electric vehicle, a hybrid electric vehicle, a motorcycle, a bicycle, a personal mobility, an airplane, a drone, a vessel, or a robot.

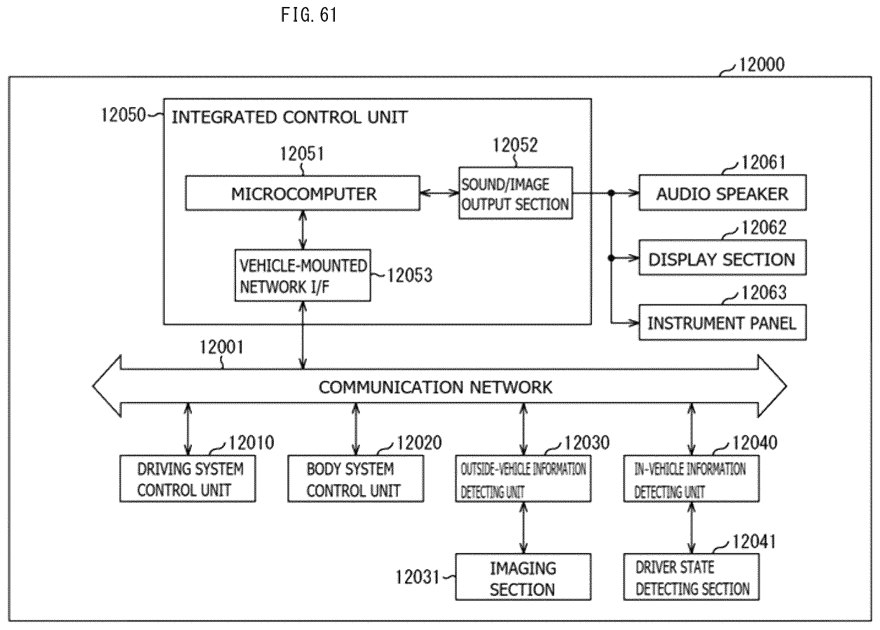

FIG. 61 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 61, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 61, an audio speaker 12061, a display section 12062, and an instrument panel 12063 are illustrated as the output device. The display section 12062 may, for example, include at least one of an on-board display and a head-up display.

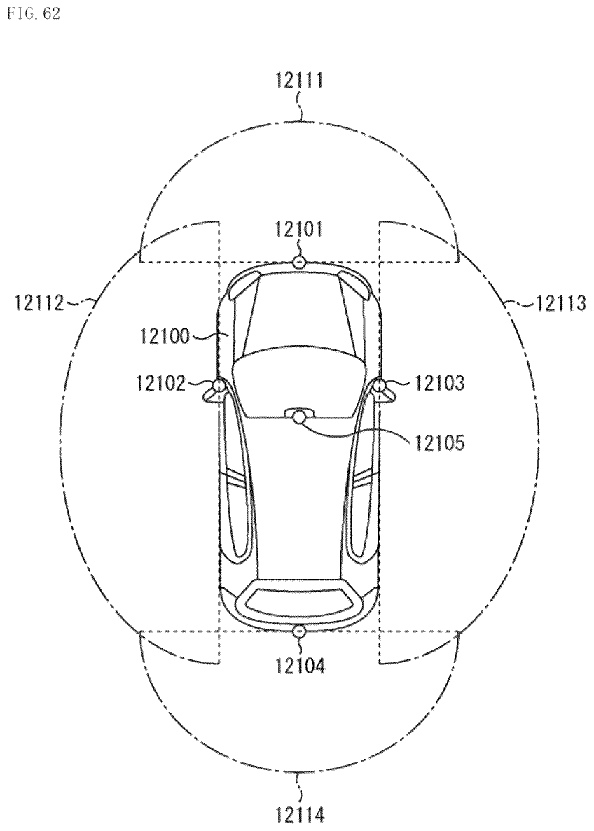

FIG. 62 is a diagram depicting an example of the installation position of the imaging section 12031.

In FIG. 62, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 62 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of an example of the vehicle control system to which the technique according to the present disclosure is applicable. The technique according to the present disclosure is applicable to, for example, the imaging section 12031 or the like, of the configurations described above. Specifically, the imaging section 12031 or the like is provided with a protective film. The protective film is stacked on a color filter between the color filter and an inter-lens partition wall. Applying the technique according to the present disclosure enables the protective film to effectively suppress or prevent damage to a surface of the color filter, in the imaging section 12031 or the like.

### 29. Other Embodiments

The present technology is not limited to the embodiments described above, and various modifications may be made without departing from the gist of the present technology.

For example, in the present technology, two or more of the foregoing embodiments may be combined, except those that have already been described.

In the present disclosure, a solid-state imaging device includes a color filter, an optical lens, and an inter-lens partition wall. The color filter is disposed at a position corresponding to a pixel. The optical lens is stacked on the color filter. The inter-lens partition wall is disposed on at least a portion of a periphery of a side surface of the optical lens at a corresponding position between the pixels.

Here, the solid-state imaging device further includes a protective film. The protective film is stacked on the color filter between the color filter and the inter-lens partition wall.

It is therefore possible, in the solid-state imaging device, to coat the color filter and to protect the color filter. This allows the protective film to protect a surface of the color filter, thus enabling the protective film to effectively suppress or prevent damage to the surface of the color filter.

Further, in the present disclosure, the solid-state imaging device has, on a front surface of the protective film on a side of the optical lens, an irregularity that is larger than a back surface thereof on a side of the color filter.

It is therefore possible for the irregularity of the protective film to scatter reflected light for incident light and thus to reduce reflected light. This makes it possible to effectively suppress or prevent a flare phenomenon.

### <Configuration of Present Technology>

The present technology has the following configurations. According to the present technology of the following configurations, it is possible to provide a solid-state imaging device that makes it possible to effectively suppress or prevent damage to a surface of a color filter.

(1)

A solid-state imaging device including:
a color filter disposed at a position corresponding to each of pixels;
an optical lens stacked on the color filter;
an inter-lens partition wall disposed on at least a portion of a periphery of a side surface of the optical lens at a corresponding position between the pixels; and
   a protective film stacked on the color filter between the color filter and the inter-lens partition wall, the protective film protecting the color filter.
      (2)

The solid-state imaging device according to (1), in which a thickness of the protective film is thinner than a thickness of the inter-lens partition wall.

(3)

The solid-state imaging device according to (1) or (2), in which the protective film has etching selectivity with respect to the inter-lens partition wall.

(4)

The solid-state imaging device according to any one of (1) to (3), in which the protective film is formed as an etching stopper film upon etching working of the inter-lens partition wall.

(5)

The solid-state imaging device according to any one of (1) to (4), in which the protective film is formed by one or more materials selected from a resin material and an inorganic material.

(6)

The solid-state imaging device according to (5), in which the resin material includes a photosensitive resin material.

(7)

The solid-state imaging device according to any one of (1) to (6), in which the protective film has a refractive index of 1.5 or more and 1.8 or less.

(8)

The solid-state imaging device according to any one of (1) to (7), in which magnitudes of respective refractive indexes of the color filter, the protective film, the optical lens, and the inter-lens partition wall are in a relationship of the following expression:

the color filter>the protective film>the optical lens>the inter-lens partition wall.

(9)

The solid-state imaging device according to any one of (1) to (8), in which
the color filter has a refractive index of 1.6 or more and 2.0 or less,
the optical lens has a refractive index of 1.5 or more and 2.0 or less, and
the inter-lens partition wall has a refractive index of 1.1 or more and less than 1.5.
   (10)

The solid-state imaging device according to any one of (1) to (9), in which
the color filter includes
   a first color filter, and
   a second color filter having a longer transmitted wavelength of light than the first color filter, and
the protective film includes
   a first protective film stacked on the first color filter, and
   a second protective film stacked on the second color filter and having a film thickness that is thicker than the first protective film.
      (11)

The solid-state imaging device according to any one of (1) to (10), in which
the color filter includes
   a first color filter, and
   a second color filter having a longer transmitted wavelength of light than the first color filter, and
the protective film includes
   a first protective film stacked on the first color filter, and
   a second protective film stacked on the second color filter and having a refractive index that is higher than the first protective film.
      (12)

The solid-state imaging device according to any one of (1) to (11), in which the protective film is formed by a plurality of layers stacked in a film thickness direction.

(13)

The solid-state imaging device according to (12), in which, among the plurality of layers of the protective film, a first layer on a side of the color filter has a smaller step difference due to a difference in a thickness of the color filter than a second layer on a side of the optical lens.

(14)

The solid-state imaging device according to (12) or (13), in which, among the plurality of layers of the protective film, the first layer on the side of the color filter has a refractive index that is higher than a refractive index of the second layer on the side of the optical lens.

(15)

The solid-state imaging device according to (13) or (14), in which, in the protective film, the first layer is formed by a resin material, and the second layer is formed by an inorganic material.

(16)

The solid-state imaging device according to any one of (1) to (15), in which a first surface of the protective film on the side of the optical lens is provided with an irregularity that is larger than a second surface on the side of the color filter.

(17)

The solid-state imaging device according to (16), in which the irregularity of the first surface is larger at a middle part of each of the pixels than a peripheral part of each of the pixels.

(18)

The solid-state imaging device according to (16) or (17), in which
a pixel region is provided in which a plurality of the pixels is arrayed, and
the irregularity of the first surface of the protective film is larger at a middle portion of the pixel region than a peripheral portion of the pixel region.
   (19)

The solid-state imaging device according to any one of (16) to (18), in which
the color filter includes
   the first color filter, and
   the second color filter having a longer transmitted wavelength of light than the first color filter, and
the irregularity of the first surface of the protective film stacked on the second color filter is larger than the irregularity of the first surface of the protective film stacked on the first color filter.
   (20)

The solid-state imaging device according to any one of (1) to (19), in which
the optical lens includes
   a first lens main body, and
   a second lens main body stacked on the first lens main body on a side opposite to the color filter, and
the inter-lens partition wall is disposed between a plurality of the first lens main bodies.
   (21)

The solid-state imaging device according to any one of (1) to (20), in which
a pixel region is provided in which the plurality of the pixels is arrayed, and
a plurality of the inter-lens partition walls having different widths is disposed at opposed positions of the peripheral part of each of the pixels of at least a portion of the pixel region.
   (22)

The solid-state imaging device according to (21), in which one of the inter-lens partition walls having different widths overhangs to a side of another of the inter-lens partition walls having different widths.

(23)

The solid-state imaging device according to (22), in which an amount of the overhanging of the one of the inter-lens partition walls varies from the middle portion toward the peripheral portion of the pixel region.

(24)

The solid-state imaging device according to any one of (21) to (23), in which each of the pixels interposed between the inter-lens partition walls having different widths constructs a phase difference detection pixel.

The present application claims the benefit of Japanese Priority Patent Application JP2022-069621 filed with the Japan Patent Office on Apr. 20, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. A solid-state imaging device, comprising:
a color filter disposed at a position corresponding to each of pixels;
an optical lens stacked on the color filter;
an inter-lens partition wall disposed on at least a portion of a periphery of a side surface of the optical lens at a corresponding position between the pixels; and
a protective film stacked on the color filter between the color filter and the inter-lens partition wall, the protective film protecting the color filter.

2. The solid-state imaging device according to claim 1, wherein a thickness of the protective film is thinner than a thickness of the inter-lens partition wall.

3. The solid-state imaging device according to claim 1, wherein the protective film has etching selectivity with respect to the inter-lens partition wall.

4. The solid-state imaging device according to claim 3, wherein the protective film is formed as an etching stopper film upon etching working of the inter-lens partition wall.

5. The solid-state imaging device according to claim 1, wherein the protective film is formed by one or more materials selected from a resin material and an inorganic material.

6. The solid-state imaging device according to claim 5, wherein the resin material comprises a photosensitive resin material.

7. The solid-state imaging device according to claim 5, wherein the protective film has a refractive index of 1.5 or more and 1.8 or less.

8. The solid-state imaging device according to claim 1, wherein magnitudes of respective refractive indexes of the color filter, the protective film, the optical lens, and the inter-lens partition wall are in a relationship of the following expression:
the color filter>the protective film>the optical lens>the inter-lens partition wall.

9. The solid-state imaging device according to claim 8, wherein
the color filter has a refractive index of 1.6 or more and 2.0 or less,
the optical lens has a refractive index of 1.5 or more and 2.0 or less, and
the inter-lens partition wall has a refractive index of 1.1 or more and less than 1.5.

10. The solid-state imaging device according to claim 1, wherein
the color filter includes
a first color filter, and
a second color filter having a longer transmitted wavelength of light than the first color filter, and
the protective film includes
a first protective film stacked on the first color filter, and
a second protective film stacked on the second color filter and having a film thickness that is thicker than the first protective film.

11. The solid-state imaging device according to claim 1, wherein
the color filter includes
a first color filter, and
a second color filter having a longer transmitted wavelength of light than the first color filter, and
the protective film includes
a first protective film stacked on the first color filter, and
a second protective film stacked on the second color filter and having a refractive index that is higher than the first protective film.

12. The solid-state imaging device according to claim 1, wherein the protective film is formed by a plurality of layers stacked in a film thickness direction.

13. The solid-state imaging device according to claim 12, wherein, among the plurality of layers of the protective film, a first layer on a side of the color filter has a smaller step difference due to a difference in a thickness of the color filter than a second layer on a side of the optical lens.

14. The solid-state imaging device according to claim 12, wherein, among the plurality of layers of the protective film, a first layer on a side of the color filter has a refractive index that is higher than a refractive index of a second layer on a side of the optical lens.

15. The solid-state imaging device according to claim 13, wherein, in the protective film, the first layer is formed by a resin material, and the second layer is formed by an inorganic material.

16. The solid-state imaging device according to claim 1, wherein a first surface of the protective film on a side of the optical lens is provided with an irregularity that is larger than a second surface on a side of the color filter.

17. The solid-state imaging device according to claim 16, wherein the irregularity of the first surface is larger at a middle part of each of the pixels than a peripheral part of each of the pixels.

18. The solid-state imaging device according to claim 16, wherein
a pixel region is provided in which a plurality of the pixels is arrayed, and
the irregularity of the first surface of the protective film is larger at a middle portion of the pixel region than a peripheral portion of the pixel region.

19. The solid-state imaging device according to claim 16, wherein
the color filter includes
a first color filter, and
a second color filter having a longer transmitted wavelength of light than the first color filter, and
the irregularity of the first surface of the protective film stacked on the second color filter is larger than the irregularity of the first surface of the protective film stacked on the first color filter.

20. The solid-state imaging device according to claim 1, wherein
the optical lens includes
a first lens main body, and
a second lens main body stacked on the first lens main body on a side opposite to the color filter, and
the inter-lens partition wall is disposed between a plurality of the first lens main bodies.
